(19) United States
(12) Patent Application Publication
(10) Pub. No.: US 2026/0154244 A1
(43) Pub. Date: Jun. 4, 2026

(54) COHORT-LEVEL DATA COMPRESSION AND ENTITY-LEVEL PRIORITIZATION IN MULTI-FACTOR DATASETS

(71) Applicant: Optum Services (Ireland) Limited, Dublin (IE)

(72) Inventors: Breanndan O CONCHUIR, Killarney (IE); Ciarán McKENNA, Dublin (IE); Evan Christopher DOLAN, Dublin (IE); Matthew ROBINSON, Greystones (IE); Eugene Edward FARRELL, Clarinbridge (IE); Kieran O'DONOGHUE, Dublin (IE)

(21) Appl. No.: 18/967,150

(22) Filed: Dec. 3, 2024

(51) Int. Cl. G06F 16/215; G06F 9/451; G06F 30/20

(52) U.S. Cl. CPC G06F 16/215; G06F 9/451; G06F 30/20

(57) ABSTRACT

Various embodiments of the present disclosure provide a data compression pipeline that improves the functionality of a computer in various aspects. The techniques comprise receiving an entity cohort file, extracting a cohort-level optimization dataset from the entity cohort file, generating, using a first and second predictive model, a scaled risk score and a scaled event score for an entity represented within the entity cohort file, generating a cohort score for the entity cohort file based on the scaled risk score, the scaled event score, and the subset of target entities of the cohort-level optimization dataset, and storing a compressed entity cohort file that identifies the cohort score, the subset of target entities, and an entity-level score for each entity within the subset of target entities.

### BACKGROUND

Various embodiments of the present disclosure address technical challenges related to big data, including the compression, retrieval, and prioritization of robust, multi-factored datasets. In various domains, prioritization of entities within large, multi-factored datasets presents significant computational challenges, particularly when considering multiple complex attributes and metrics simultaneously. Traditional approaches rely on rule-based systems and/or stratification techniques that fail to capture the nuanced interplay between different entity attributes and their impacts on overall performance metrics. This leads to performance deficiencies with effectively combining disparate data types and sources in a computationally efficient manner. For example, binary coded attributes and categorical attributes traditionally require different processing approaches, leading to siloed analyses that fail to leverage potential synergies between these data types.

The lack of a coherent process for compressing different sets of data within a multi-factored dataset necessitates the storage, maintenance, and transfer of each individual set of data to represent the multi-factored dataset to different computing entities and/or the users thereof. Thus, multi-factored datasets traditionally require robust computing resources, including memory and processing resources, for storing the data within memory and transferring representations of the data across different computing entities. This leads to scalability issues when dealing with a plurality of different multi-factored dataset due to prohibitively large computational overhead and messaging times needed to transfer, store, and interpret each dataset. Moreover, once stored and/or transferred, comparisons between uncompressed representations of multi-factored datasets require complex analytical tools that require processing resources, time, and memory traditionally unavailable on local computing devices. This leads to prioritization challenges in limited processing environments, such as client devices in which local processing techniques may be limited to the processing capabilities of a small hardware package.

Various embodiments of the present disclosure make important contributions to traditional data compression, retrieval, and prioritization technologies by addressing these technical challenges, among others.

### BRIEF DESCRIPTION OF THE DRAWINGS

FIG. 1 depicts an example overview of an architecture in accordance with some embodiments of the present disclosure.

FIG. 2 depicts an example predictive data analysis computing entity in accordance with some embodiments of the present disclosure.

FIG. 3 depicts an example client computing entity in accordance with some embodiments of the present disclosure.

FIG. 4 depicts a dataflow diagram of a data compression pipeline in accordance with some embodiments of the present disclosure.

FIG. 5 depicts a dataflow diagram of a data compression technique in accordance with some embodiments of the present disclosure.

FIG. 6 depicts an operational example of a first branch of the first predictive model in accordance with some embodiments of the present disclosure.

FIGS. 7A-B depict operational examples of a first predictive model outputs in accordance with some embodiments of the present disclosure.

FIG. 8 depicts an operational example of a graph-based causal model architecture in accordance with some embodiments of the present disclosure.

FIG. 9 depicts an operational example of a second predictive model output in accordance with some embodiments of the present disclosure.

FIG. 10 depicts a flowchart diagram of data compression process in accordance with some embodiments of the present disclosure.

### DETAILED DESCRIPTION

Various embodiments of the present disclosure provide a data compression pipeline that improves the functionality of computer systems with respect to data compression generally and several downstream computing operations, including data storage, retrieval, entity prioritization, resource allocation, among others. To do so, the data compression pipeline synthesizes intermediate outputs from three, traditionally incompatible data processing techniques to comprehensively represent a large, multi-factor entity cohort file with a single prediction that accounts for multiple different, data types representing different facets of the multi-factor entity cohort file. By doing so, the data compression pipeline may compress the multi-factor entity cohort file to the single prediction with contextual, entity-level attributes that may be used to reduce the file size of the entity cohort file and, in turn, optimize memory usage while reducing computational overhead.

More particularly, to overcome performance deficiencies with traditional data analysis techniques, the techniques (e.g., hardware, software, machine-learned model(s), computer-implemented method(s), system(s), and/or one or more non-transitory computer-readable media) of the present disclosure apply scaling coefficients to synthesize intermediate outputs from entity-level risk and event scoring model architectures that are individual configured to process an entity cohort file accordingly to different processing techniques to provide intermediate outputs of different, incompatible data types. For instance, an entity-level risk model (e.g., a first predictive model) may comprise a multi-branched model ensemble that routes an entity through a different combination of rule-based and machine learned layers to evaluate a risk score for the entity. In a parallel processing stream, an event scoring model (e.g., a second predictive model) may comprise a graph-based causal model that processes the entity by traversing different graphs corresponding to the attributes of the entity. Each predictive model may output a prediction for a non-overlapping metric of an entity that is traditionally used in an individualized capacity to represent a portion of the entity's attributes. To synthesize these predictions, the data compression pipeline augments each model architecture with a scaling layer configured to convert each prediction to a compatible type. By doing so, the data compression pipeline enables the compression to two, disparate measurements represented by different sets of data into a single value that may be used within a compressed entity cohort file to represent both sets of data at reduced data transmission and storage costs.

In some embodiments of the present disclosure, the scaled intermediate outputs from the entity-level risk and event scoring model architectures may be synthesized with other intermediate outputs to further compress the entity cohort file without information loss. For example, by scaling the intermediate outputs, the data compression pipeline enables the integration of entity-level prediction outputs with cohort level prediction outputs, such as a cohort-level optimization dataset, which are optimized based on cohort-level metrics. This enables the layering of entity-level performance metrics within a reduced size cohort of entities. By doing so, the data compression pipeline of the present disclosure may reduce a cohort size without losing the contextual granularities provided by an original dataset. These contextual granularities (e.g., scaled event score, scaled risk score) improve the interpretability of a compressed entity cohort file, reduce information loss through the compression of the entity cohort file to the compressed entity cohort file, and enable entity-level prioritization functions and downstream actions. By way of example, as described in further detail herein, by overlaying the entity-level performance metrics (e.g., scaled event score, scaled risk score) within a compressed, cohort-level optimization dataset, some techniques of the present disclosure may prioritize physical actions tailored to a prediction domain, including the administration of medications as needed in a clinical domain, blocking entity-level access to different computing resources in a computer security domain, among other examples.

In some embodiments of the present disclosure, by compressing the entity cohort files themselves using a single value (e.g., a cohort score), the data compression pipeline improves the storage capacity, data retrieval times, and cohort-level comparisons between different large, multi-factored datasets. This enables the client-side retrieval, comparison, and storage of multiple, traditionally large entity cohort files. In doing so, the data compression pipeline improves client-level access to traditionally inaccessible datasets by compressing the dataset to a size accessible by small hardware packages. Moreover, unlike their uncompressed counterparts, the compressed representations may be arranged as selectable icons within an improved electronic interface that enables direct interactions with and navigation of complex datasets unique to computers.

Examples of technologically advantageous embodiments of the present disclosure comprise improved data compression, storage, and retrieval techniques, user interfaces, and machine learning pipelines, among other aspects of the present disclosure. Other technical improvements and advantages may be realized by one of ordinary skill in the art.

### I. EMBODIMENTS OVERVIEW

As should be appreciated, various embodiments of the present disclosure may be implemented as methods, apparatus, systems, computing devices, computing entities, computer program products, and/or the like. As such, embodiments of the present disclosure may take the form of an apparatus, system, computing device, computing entity, and/or the like executing instructions stored on a computer-readable storage medium to perform certain steps or operations. Thus, embodiments of the present disclosure may take the form of an entirely hardware embodiment, an entirely computer program product embodiment, and/or an embodiment that comprises a combination of computer program products and hardware performing certain steps or operations.

Embodiments of the present disclosure are described below with reference to block diagrams and flowchart illustrations. Thus, it should be understood that each block of the block diagrams and flowchart illustrations may be implemented in the form of a computer program product, an entirely hardware embodiment, a combination of hardware and computer program products, and/or apparatus, systems, computing devices, computing entities, and/or the like carrying out instructions, operations, steps, and similar words used interchangeably (e.g., the executable instructions, instructions for execution, program code, and/or the like) on a computer-readable storage medium for execution. For example, retrieval, loading, and execution of code may be performed sequentially such that one instruction is retrieved, loaded, and executed at a time. In some example embodiments, retrieval, loading, and/or execution may be performed in parallel such that multiple instructions are retrieved, loaded, and/or executed together. Thus, such embodiments may produce specifically configured machines performing the steps or operations specified in the block diagrams and flowchart illustrations. Accordingly, the block diagrams and flowchart illustrations support various combinations of embodiments for performing the specified instructions, operations, or steps.

### II. EXAMPLE FRAMEWORK

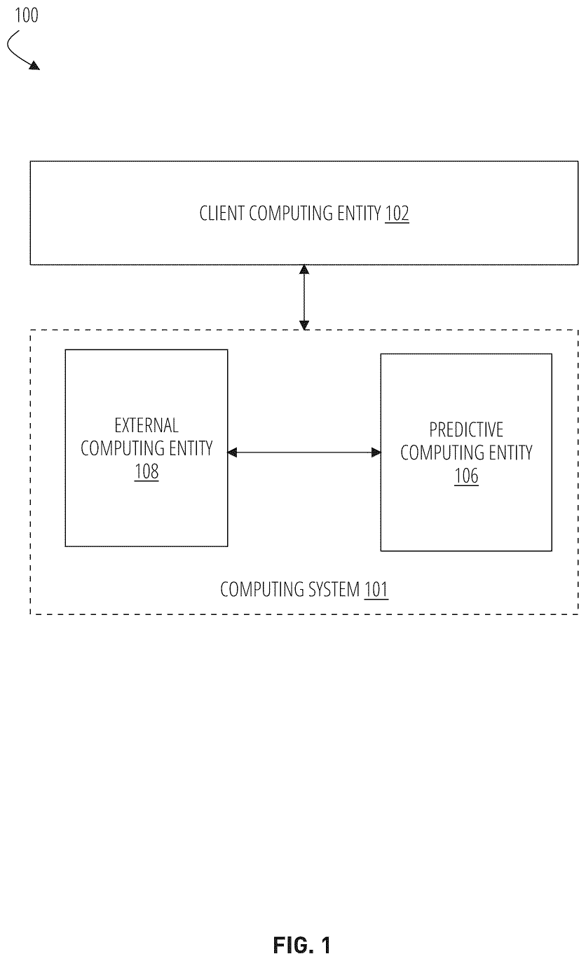

FIG. 1 provides an example overview of an architecture 100 in accordance with some embodiments of the present disclosure. The architecture 100 comprises a computing system 101 configured to receive a request (e.g., a data compression request, data retrieval request) from client computing entities 102, process the request, and provide responses (e.g., a compressed entity cohort file) to the client computing entities 102. The example architecture 100 may be used in a plurality of domains and is not limited to any specific application as disclosed herewith. The plurality of domains may comprise industrial, manufacturing, computer security, to name a few.

In accordance with various embodiments of the present disclosure, one or more machine learning models may be trained to generate intermediate outputs (e.g., risk score, engagement scores) of a data compression pipeline. The models, for example, may be adapted to the data compression pipeline configured to compress an entity cohort file to a compressed entity cohort file to improve the transferability and storage requirement of the entity cohort file. Some techniques of the present disclosure may adapt traditional models to a cohesive framework, such as the data compression pipeline, for more efficiently handling portions of the request.

In some embodiments, the computing system 101 may communicate with at least one of the client computing entities 102 using one or more communication networks. Examples of communication networks comprise any wired or wireless communication network including, for example, a wired or wireless local area network (LAN), personal area network (PAN), metropolitan area network (MAN), wide area network (WAN), or the like, as well as any hardware, software, and/or firmware required to implement it (such as, e.g., network routers, and/or the like).

The computing system 101 may comprise a predictive computing entity 106 and one or more external computing entities 108. The predictive computing entity 106 and/or one or more external computing entities 108 may be individually and/or collectively configured to receive requests from client computing entities 102, process the requests to generate responses, and provide the responses to the client computing entities 102.

For example, as discussed in further detail herein, the predictive computing entity 106 and/or one or more external computing entities 108 comprise storage subsystems that may be configured to store input data, training data, and/or the like that may be used by the respective computing entities to perform predictive data analysis and/or training operations of the present disclosure. In addition, the storage subsystems may be configured to store model definition data used by the respective computing entities to perform various predictive data processing and/or training tasks. The storage subsystem may comprise one or more storage units, such as multiple distributed storage units that are connected through a computer network. A storage unit in the respective computing entities may store at least one of one or more data assets and/or a set of data about the computed properties of one or more data assets. Moreover, each storage unit in the storage systems may comprise one or more non-volatile storage or volatile storage media similar to or different than the non-volatile and/or volatile computer-readable storage media discussed above.

In some embodiments, the predictive computing entity 106 and/or one or more external computing entities 108 are communicatively coupled using one or more wired and/or wireless communication techniques. The respective computing entities may be configured according to the techniques described herein to perform one or more operations of one or more techniques described herein. By way of example, the predictive computing entity 106 may be configured to train, implement, use (e.g., execute an inference operation(s)), update (e.g., fine-tune), and evaluate machine learning models in accordance with one or more training and/or inference operations of the present disclosure. In some examples, the external computing entities 108 may be configured to train, implement, use, update, and evaluate machine learning models in accordance with one or more training and/or inference operations of the present disclosure.

In some example embodiments, the predictive computing entity 106 may be configured to receive and/or transmit one or more datasets, objects, and/or the like from and/or to the external computing entities 108 to perform one or more steps/operations of one or more techniques (e.g., data compression) described herein. The external computing entities 108, for example, may comprise and/or be associated with one or more entities that may be configured to receive, transmit, store, manage, and/or facilitate datasets, and/or the like. The external computing entities 108, for example, may comprise data sources that may provide such datasets, and/or the like to the predictive computing entity 106 which may leverage the datasets, such as the domain datastore, entity cohort files, compressed entity cohort files, and/or the like to perform one or more steps/operations of the present disclosure, as described herein. In some examples, the datasets may comprise an aggregation of data from across a plurality of external computing entities 108 into one or more aggregated datasets. The external computing entities 108, for example, may be associated with one or more data repositories, cloud platforms, compute nodes, organizations, and/or the like, which may be individually and/or collectively leveraged by the predictive computing entity 106 to obtain and aggregate data for an information domain.

In some example embodiments, the predictive computing entity 106 may be configured to receive a trained machine learning model trained and subsequently provided by the one or more external computing entities 108. For example, the one or more external computing entities 108 may be configured to perform one or more training steps/operations of the present disclosure to train a machine learning model, as described herein. In such a case, the trained machine learning model may be provided to the predictive computing entity 106, which may leverage the trained machine learning model to perform one or more inference steps/operations of the present disclosure. In some examples, feedback (e.g., evaluation data, ground truth data) from the use of the machine learning model may be recorded by the predictive computing entity 106. In some examples, the feedback may be provided to the one or more external computing entities 108 to continuously train the machine learning model over time. In some examples, the feedback may be leveraged by the predictive computing entity 106 to continuously train the machine learning model over time. In this manner, the computing system 101 may perform, via one or more combinations of computing entities, one or more prediction, training, and/or any other machine learning-based techniques of the present disclosure.

### A. Example Computing Entity

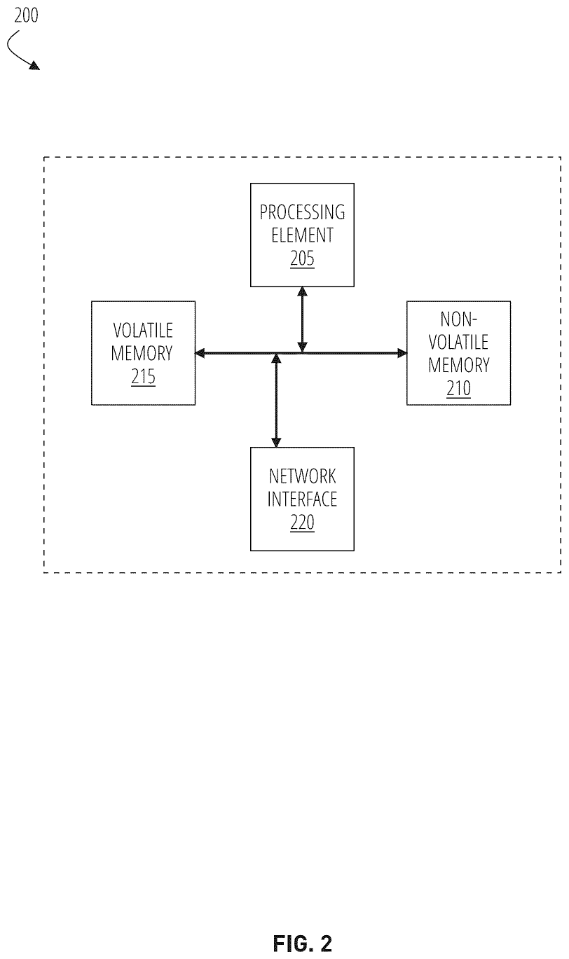

FIG. 2 provides an example computing entity 200 in accordance with some embodiments of the present disclosure. The computing entity 200 is an example of the predictive computing entity 106 and/or external computing entities 108 of FIG. 1. In general, the terms computing entity, computer, entity, device, system, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Such functions, operations, and/or processes may comprise, for example, transmitting, receiving, operating on, processing, displaying, storing, determining, creating/generating, training one or more machine learning models, monitoring, evaluating, comparing, and/or similar terms used herein interchangeably. In some embodiments, these functions, operations, and/or processes may be performed on data, content, information, and/or similar terms used herein interchangeably. In some embodiments, the one computing entity (e.g., predictive computing entity 106) may train and use one or more machine learning models described herein. In other embodiments, a first computing entity (e.g., predictive computing entity 106, which may be one or more predictive computing entities) may use one or more machine learning models that may be trained by a second computing entity (e.g., external computing entity 108) communicatively coupled to the first computing entity. The second computing entity, for example, may train one or more of the machine learning models described herein, and subsequently provide the trained machine learning model(s) (e.g., optimized weights, code sets) to the first computing entity over a network.

As shown in FIG. 2, in some embodiments, the computing entity 200 may comprise, or be in communication with, one or more processing elements 205 (also referred to as processors, processing circuitry, and/or similar terms used herein interchangeably) that communicate with other elements within the computing entity 200 via a bus, for example. As will be understood, the processing element 205 may be embodied in a number of different ways.

For example, the processing element 205 may be embodied as one or more complex programmable logic devices (CPLDs), microprocessors, multi-core processors, arithmetic logic units (ALUs) (e.g., which may be part of one or more graphics processing units (GPUs), tensor processing units (TPUs), and/or the like), coprocessing entities, application-specific instruction-set processors (ASIPs), microcontrollers, and/or controllers. Additionally, or alternatively, the processing element 205 may be embodied as one or more other processing devices and/or circuitry. The term circuitry may refer to an entirely hardware embodiment or a combination of hardware and computer program products. Examples of a combination of hardware and computer program products comprise application specific integrated circuits (ASICs), field programmable gate arrays (FPGAs), programmable logic arrays (PLAs), hardware accelerators, other circuitry, and/or the like.

As will therefore be understood, the processing element 205 may be configured for a particular use or configured to execute instructions stored in volatile or non-volatile media or otherwise accessible to the processing element 205. As such, whether configured by hardware or computer program products, or by a combination thereof, the processing element 205 may be capable of performing steps or operations according to embodiments of the present disclosure when configured accordingly.

In some embodiments, the computing entity 200 may further comprise, or be in communication with, non-transitory computer readable media, such as non-volatile memory 210 (also referred to as non-volatile media, storage, memory storage, memory circuitry, and/or similar terms used herein interchangeably) and/or volatile memory 215 (also referred to as volatile media, storage, memory storage, memory circuitry, and/or similar terms used herein interchangeably), as discussed above.

In some embodiments, non-volatile memory 210 may comprise a computer-readable storage medium may include a floppy disk, flexible disk, hard disk, solid-state storage (SSS) (e.g., a solid-state drive (SSD), solid-state card (SSC), solid-state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In some embodiments, volatile memory 215 may comprise a computer-readable storage medium including random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory (VRAM), cache memory (including various levels), flash memory, register memory, and/or the like. It will be appreciated that where embodiments are described to use a computer-readable storage medium, other types of computer-readable storage media may be substituted for or used in addition to the computer-readable storage media described above.

As will be recognized, the non-volatile memory 210 and/or the volatile memory 215 may store respective part(s) of one or more databases, database instances, database management systems, data, applications, programs, program modules, scripts, code (e.g., source code, object code, byte code, compiled code, interpreted code, machine code) that embodies one or more machine learning models or other computer functions described herein, executable instructions, and/or the like being executed by, for example, the processing element 205. The term database, database instance, database management system, and/or similar terms used herein interchangeably, may refer to a collection of records or data that is stored in a computer-readable storage medium using one or more database models; such as a hierarchical database model, network model, relational model, entity-relationship model, object model, document model, semantic model, graph model, and/or the like.

Thus, the databases, database instances, database management systems, data, applications, programs, program modules, code (source code, object code, byte code, compiled code, interpreted code, machine code) that embodies one or more machine learning models or other computer functions described herein, executable instructions, and/or the like may be used to control certain aspects of the operation of the computing entity 200 by operating the processing element 205 according to software component(s) retrieved from any of the computer-readable storage media and executed by the processing element 205.

Embodiments of the present disclosure may be implemented in various ways, including as computer program products that comprise articles of manufacture. Such computer program products may comprise one or more software components including, for example, software objects, methods, data structures, or the like. A software component may be coded in any of a variety of programming languages. An illustrative programming language may be a lower-level programming language such as an assembly language associated with a particular hardware architecture and/or operating system platform. A software component comprising assembly language instructions may require conversion into executable machine code by an assembler prior to execution by the hardware architecture and/or platform. Another example programming language may be a higher-level programming language that may be portable across multiple architectures. A software component comprising higher-level programming language instructions may require conversion to an intermediate representation by an interpreter or a compiler prior to execution.

Other examples of programming languages comprise, but are not limited to, a macro language, a shell or command language, a job control language, a script language, a database query or search language, and/or a report writing language. In one or more example embodiments, a software component comprising instructions in one of the foregoing examples of programming languages may be executed directly by an operating system or other software component without having to be first transformed into another form, such as object code, or may be first transformed into another form, such as by compiling source code. A software component may be stored as a file or other data storage construct. Software components of a similar type or functionally related may be stored together such as, for example, in a particular directory, folder, or library. Software components may be static (e.g., pre-established, or fixed) or dynamic (e.g., created or modified at the time of execution).

A computer program product may comprise a non-transitory computer-readable storage medium storing one or more software components comprising application(s), program(s), program module(s), script(s), source code and/or compiler(s) for generating executable instructions such as object code using the source code, program code, object code, byte code, compiled code, interpreted code, machine code, executable instructions, and/or the like (e.g., executable instructions, instructions for execution, computer program products, program code, and/or similar terms used herein interchangeably). Such non-transitory computer-readable storage media comprise all computer-readable storage media (including volatile memory 215 and non-volatile memory 210). In some embodiments, the computer program product may be executed by the computing entity 200 and/or the client computing entity. For example, at least a first portion of the computer program product may be stored within the volatile memory 215 and/or non-volatile memory 210 of the computing entity 200. In addition, or alternatively, at least a second portion of the computer program product may be stored within the volatile and/or non-volatile memory of a client computing entity.

As indicated, in some embodiments, the computing entity 200 may also comprise one or more network interfaces 220 for communicating with various computing entities (e.g., the client computing entity 102, external computing entities), such as by communicating data, code, content, information, and/or similar terms used herein interchangeably that may be transmitted, received, operated on, processed, displayed, stored, and/or the like. Such communication may be executed using a wired data transmission protocol, such as fiber distributed data interface (FDDI), digital subscriber line (DSL), Ethernet, asynchronous transfer mode (ATM), frame relay, data over cable service interface specification (DOCSIS), or any other wired transmission protocol. In some embodiments, the computing entity 200 communicates with another computing entity for uploading or downloading data or code (e.g., data or code that embodies or is otherwise associated with one or more machine learning models). Similarly, the computing entity 200 may be configured to communicate via wireless external communication networks using any of a variety of protocols, such as general packet radio service (GPRS), Universal Mobile Telecommunications System (UMTS), Code Division Multiple Access 2000 (CDMA2000), CDMA2000 1× (1×RTT), Wideband Code Division Multiple Access (WCDMA), Global System for Mobile Communications (GSM), Enhanced Data rates for GSM Evolution (EDGE), Time Division-Synchronous Code Division Multiple Access (TD-SCDMA), Long Term Evolution (LTE), Evolved Universal Terrestrial Radio Access Network (E-UTRAN), Evolution-Data Optimized (EVDO), High Speed Packet Access (HSPA), High-Speed Downlink Packet Access (HSDPA), IEEE 802.11 (Wi-Fi), Wi-Fi Direct, IEEE 802.16 (WiMAX), ultra-wideband (UWB), infrared (IR) protocols, near field communication (NFC) protocols, Wibree, Bluetooth protocols, wireless universal serial bus (USB) protocols, and/or any other wireless protocol.

Although not shown, the computing entity 200 may additionally or alternatively comprise, or be in communication with, one or more input elements/devices, such as input sensor(s). In some examples, the input sensor(s) may comprise one or more keyboards, pointing devices (e.g., mouse, trackpad), touch screens, cameras (e.g., infrared light camera, visual light camera), depth sensors (e.g., LIDAR, radar, stereo cameras), gyroscopes, location sensors (e.g., global positioning system (GPS), Hall effect sensor, laser doppler vibrometer), microphones, and/or the like. The computing entity 200 may additionally or alternatively comprise, or be in communication with, one or more output elements/devices (not shown), such as one or more speakers, visual display devices, haptic feedback devices, motion devices (e.g., electromechanically actuated devices), and/or the like.

### B. Example Client Computing Entity

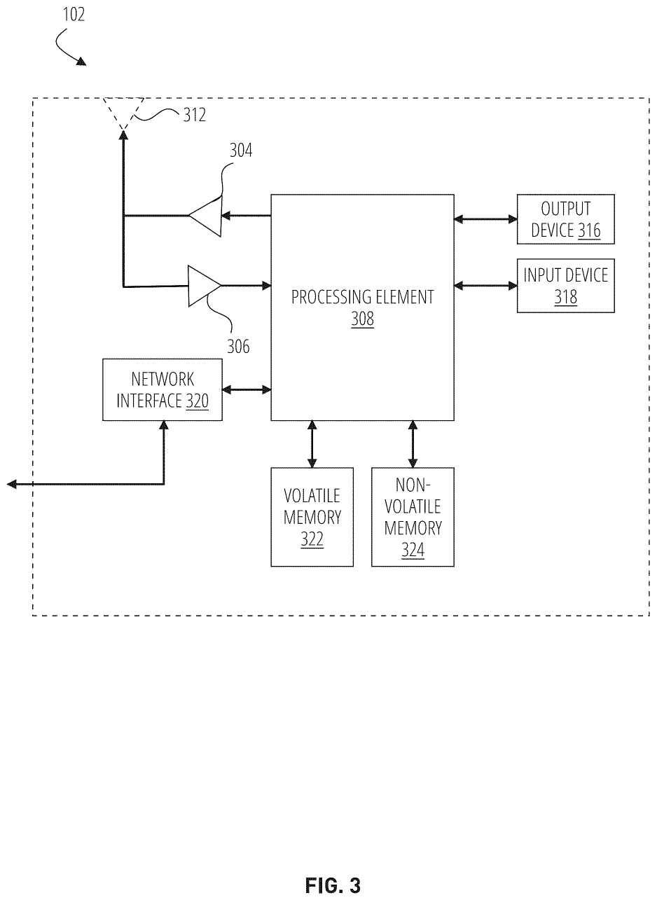

FIG. 3 provides an example client computing entity in accordance with some embodiments of the present disclosure. In general, the terms device, system, computing entity, entity, and/or similar words used herein interchangeably may refer to, for example, one or more computers, computing entities, desktops, mobile phones, tablets, phablets, notebooks, laptops, distributed systems, kiosks, input terminals, servers or server networks, blades, gateways, switches, processing devices, processing entities, set-top boxes, relays, routers, network access points, base stations, the like, and/or any combination of devices or entities adapted to perform the functions, operations, and/or processes described herein. Client computing entities 102 may be operated by various parties. As shown in FIG. 3, the client computing entity 102 may comprise an antenna 312, a transmitter 304 (e.g., radio), a receiver 306 (e.g., radio), and a processing element 308 (e.g., CPLDs, microprocessors, multi-core processors, coprocessing entities, ASIPs, microcontrollers, and/or controllers) that provides signals to and receives signals from the transmitter 304 and receiver 306, correspondingly.

The signals provided to and received from the transmitter 304 and the receiver 306, correspondingly, may comprise signaling information/data in accordance with air interface standards of applicable wireless systems. In this regard, the client computing entity 102 may be capable of operating with one or more air interface standards, communication protocols, modulation types, and access types. More particularly, the client computing entity 102 may operate in accordance with one or more wireless and/or wired communication standards and protocols, such as those described above with regard to the computing entity 200.

The client computing entity 102 may additionally or alternatively download code, changes, add-ons, and updates, for instance, to its firmware, software (e.g., including executable instructions, applications, program modules), and operating system.

According to some embodiments, the client computing entity 102 may comprise location determining aspects, devices, modules, functionalities, and/or similar words used herein interchangeably. For example, the client computing entity 102 may comprise outdoor positioning aspects, such as a location component adapted to acquire, for example, latitude, longitude, altitude, geocode, course, direction, heading, speed, universal time (UTC), date, and/or various other information/data. In some embodiments, the location component may acquire data, sometimes known as ephemeris data, by identifying the number of satellites in view and the relative positions of those satellites (e.g., using global positioning systems (GPS)). The satellites may be a variety of different satellites, including Low Earth Orbit (LEO) satellite systems, Department of Defense (DOD) satellite systems, the European Union Galileo positioning systems, the Chinese Compass navigation systems, Indian Regional Navigational satellite systems, and/or the like. This data may be collected using a variety of coordinate systems, such as the Decimal Degrees (DD); Degrees, Minutes, Seconds (DMS); Universal Transverse Mercator (UTM); Universal Polar Stereographic (UPS) coordinate systems; and/or the like. Alternatively, the location information/data may be determined by triangulating the position of the client computing entity 102 in connection with a variety of other systems, including cellular towers, Wi-Fi access points, and/or the like. Similarly, the client computing entity 102 may comprise indoor positioning aspects, such as a location component adapted to acquire, for example, latitude, longitude, altitude, geocode, course, direction, heading, speed, time, date, and/or various other information/data. Some of the indoor systems may use various position or location technologies including RFID tags, indoor beacons or transmitters, Wi-Fi access points, cellular towers, nearby computing devices (e.g., smartphones, laptops), and/or the like. For instance, such technologies may comprise the iBeacons, Gimbal proximity beacons, Bluetooth Low Energy (BLE) transmitters, NFC transmitters, and/or the like. These indoor positioning aspects may be used in a variety of settings to determine the location of someone or something to within inches or centimeters.

The client computing entity 102 may also comprise a user interface (that may comprise an output device 316) coupled to a processing element 308 and/or a user input device coupled to the processing element 308. In some examples, the user interface may additionally or alternatively comprise software component(s) executed by the processing element 308 to present (e.g., audibly, visually, tactilely) via an input and/or output device and/or a software endpoint such as an application programming interface (API) or exposed software function a graphical user interface (GUI) (e.g., at least a portion of a user application, browser), command-line interface, touch and/or haptic user interface, gesture and/or image capture-based interface, voice/audio user interface, and/or the like used herein interchangeably executing on and/or accessible via the client computing entity 102 to interact with and/or cause display of information/data from the computing entity 200, as described herein. In addition to providing input, the user input interface may be used, for example, to activate, deactivate, and/or modify certain functions, such as altering a power or operating state of the client computing entity 102, the computing system 101, the predictive computing entity 106, and/or the external computing entity 108.

The client computing entity 102 may further comprise, or be in communication with, non-transitory computer readable media, such as non-volatile media (also referred to as non-volatile storage, memory, memory storage, memory circuitry, and/or similar terms used herein interchangeably) and/or volatile media (also referred to as volatile storage, memory, memory storage, memory circuitry, and/or similar terms used herein interchangeably), as discussed above.

As will be recognized, the non-volatile media and/or the volatile media may store respective part(s) of one or more databases, database instances, database management systems, data, applications, programs, program modules, scripts, code (e.g., source code, object code, byte code, compiled code, interpreted code, machine code) that embodies one or more machine learning models or other computer functions described herein, executable instructions, and/or the like being executed by, for example, the processing element 205. The term database, database instance, database management system, and/or similar terms used herein interchangeably, may refer to a collection of records or data that is stored in a computer-readable storage medium using one or more database models; such as a hierarchical database model, network model, relational model, entity-relationship model, object model, document model, semantic model, graph model, and/or the like.

In another embodiment, the client computing entity 102 may comprise one or more components or functionalities that are the same or similar to those of the computing entity 200, as described in greater detail above. In one such embodiment, the client computing entity 102 downloads, e.g., via network interface 320, code embodying machine learning model(s) from the computing entity 200 so that the client computing entity 102 may run a local instance of the machine learning model(s). As will be recognized, these architectures and descriptions are provided for example purposes only and are not limited to the various embodiments.

In various embodiments, the client computing entity 102 may be embodied as an artificial intelligence (AI) computing entity (e.g., an intelligent agent machine-learned model), such as AutoGPT, Mycroft, Rhasspy, and/or the like. Accordingly, the client computing entity 102 may be configured to provide and/or receive information/data from a user via an input/output mechanism, such as a display, a camera, a speaker, a voice-activated input, and/or the like. In certain embodiments, an AI computing entity may comprise one or more predefined and executable program algorithms stored within an onboard memory storage component, and/or accessible over a network. In various embodiments, the AI computing entity may be configured to retrieve and/or execute one or more of the predefined program algorithms upon the occurrence of a predefined trigger event.

### III. EXAMPLE SYSTEM OPERATIONS

As indicated, various embodiments of the present disclosure make important technical contributions to data compression, storage, retrieval, and downstream computing operations, including electronic user interfaces and data prioritization. In particular, systems and methods are disclosed herein that implement machine learning and data compression techniques to improve data retrieval, storage, and prioritization operations for multi-factored datasets. By doing so, the machine learning and data compression techniques of the present disclosure enable improved data storage and retrieval processes that, when executed on a computer, improves computer resource allocation, electronic user interfaces, among other computing functions. This, in turn, may improve the functionality of a computer with respect to various computing tasks, including data storage, transmission, client-side processing, and the like.

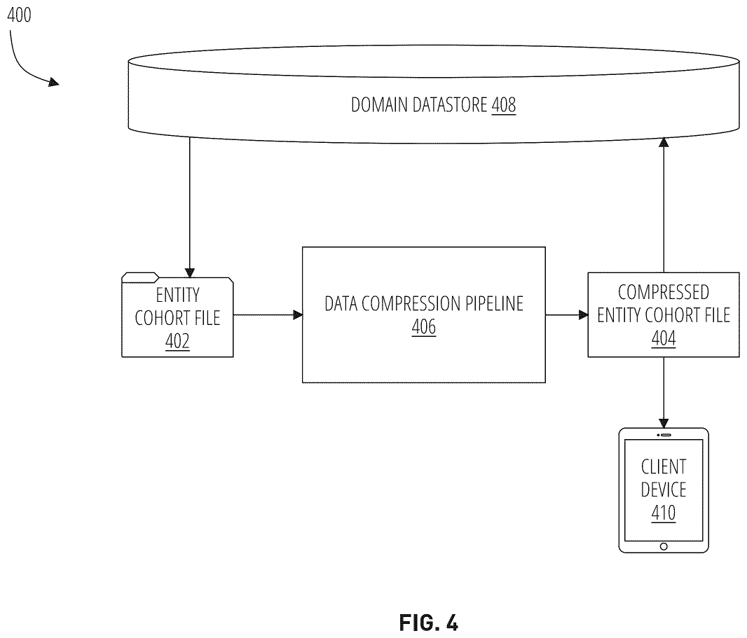

FIG. 4 is a dataflow diagram 400 of a data compression pipeline in accordance with some embodiments of the present disclosure. As illustrated by the dataflow diagram 400, a data compression pipeline 406 may be applied to an entity cohort file 402 to generate a compressed entity cohort file 404 representative of the entity cohort file 402. The compressed entity cohort file 404 may comprise a compressed representation of the entity cohort file 402 that may be stored within a domain datastore 408 and/or accessible to a client device 410. For instance, using some of the techniques of the present disclosure, the data compression pipeline 406 may receive an entity cohort file 402 from the domain datastore 408 (e.g., one or more external computing entities, such as external computing entity 108), transform the entity cohort file 402 to a compressed entity cohort file 404, and replace and/or link the compressed entity cohort file 404 with the entity cohort file 402 within the domain datastore 408 (another datastore, such as local memory).

In some embodiments, an entity cohort file 402 is a data structure that defines a cohort of entities. An entity cohort file 402, for example, may comprise a storage mechanism (e.g., database, linked list, table) that may store a plurality of indications that respectively identify a plurality of entities of an entity cohort. For instance, the entity cohort file 402 may be implemented as a database table, a spreadsheet, and/or any other structured data format that stores and organizes data for a plurality of entities within an entity cohort. In some examples, an entity cohort file 402 may comprise a plurality of historical records (e.g., historical claims, visit records) for each entity, with one or more fields corresponding to various attributes of each entity. In addition, or alternatively, the entity cohort file 402 may comprise one or more attribute vectors for an entity that comprise vectorized representations of a set of attributes (e.g., extracted from the historical records, manually input) for the entity. In some examples, the entity cohort file 402 may comprise a plurality of entity entries that each comprise an entity identifier (e.g., member identifier, patient identifier, computer identifier, server location identifier) and a plurality of entity attributes for the entity identifier. Due to the robust set of information stored within the entity cohort file 402, the entity cohort file may be associated with a large file size that (i) requires sufficient memory for storage and (ii) reduces the transferability of the entity cohort file 402 across a network. These requirements limit access to entity cohort files 402 from client devices 410, such as the interfaces of the present disclosure.

In some embodiments, an entity is a unit of an entity cohort. An entity is a single unit of the cohort that is ranked with respect to the other units to optimize downstream actions, such as different patient engagement actions within a healthcare context, different data allocation actions within a distributed computing environment, and/or the like. For example, in a healthcare context, an entity may represent an individual patient or member of a healthcare plan. An entity may be associated with various attributes, including demographic information, historical information, coded information, and other relevant data points that inform decision-making processes related to resource allocation for the entity. In some examples, each of these various attributes may be expressed as extracted attribute sets, attribute vectors, and/or the like to provide compressed representations of dense information sets for the entity that may be received, transferred, and/or input to various computer models of the present disclosure.

In some embodiments, an entity cohort is a data entity that describes a group of entities from an entity population. An entity cohort, for example, may describe a plurality of entity data objects respectively associated with a plurality of entity attributes as represented within the entity cohort file 402. The entity data objects and/or entity attributes thereof may be based on a prediction domain. For instance, an entity data object may correspond to a patient in a healthcare domain and the plurality of attributes may comprise electronic health record (EHR) data. In addition, or alternatively, an entity data object may correspond to a computer process in a computing domain and the plurality of attributes may comprise computing characteristics of the computer process, such as size, number of sub-processes, messaging protocols, and/or the like.

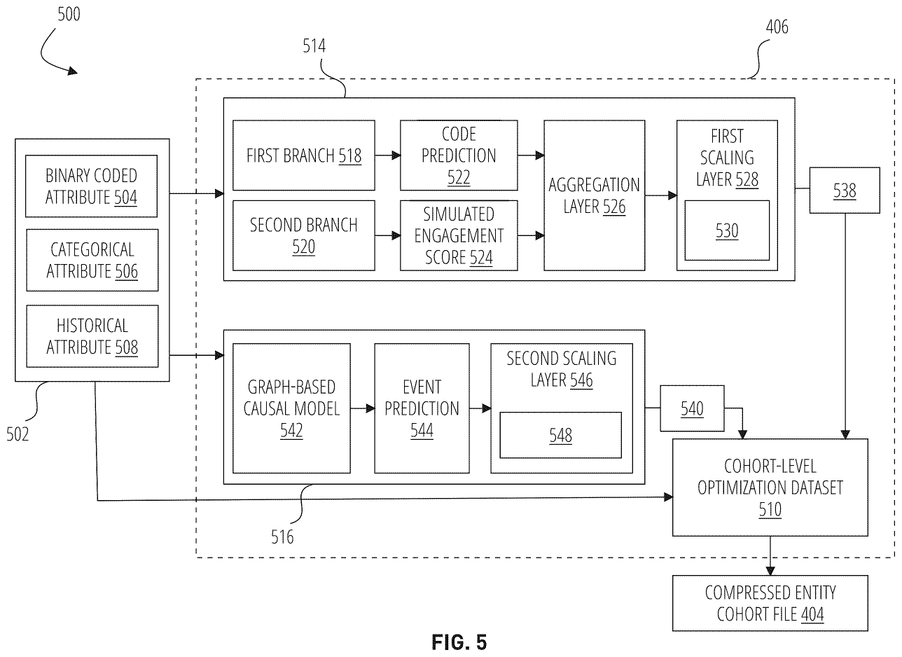

Through sequence of rule-based, machine-learned, and/or other data synthesize operations, as described with reference to FIG. 5, the data compression pipeline 406 may convert the entity cohort file 402 representing each of the attributes of each entity within an entity cohort to a compressed entity cohort file 404 that is reflective of one or more representative features of the entity cohort file 402. The representative features, for example, may comprise a cohort score, a subset of target entities, an entity-level score for each entity within the subset of target entities, and/or the like. In some examples, the compressed entity cohort file 404 may be stored in the domain datastore 408 in place of and/or linked to the entity cohort file 402. In this manner, the compressed entity cohort file 404 may provide a transferrable, interpretable, and cacheable version of the entity cohort file 402 that is accessible to the client device 410.

In some embodiments, the compressed entity cohort file 404 is a condensed data file containing ranked entity information and associated scores associated with at least a portion of the entity cohort file 402. The compressed entity cohort file 404, for example, may comprise a portion of a cohort-level optimization dataset that is augmented with a cohort score and/or one or more component scores thereof. By way of example, the compressed entity cohort file 404 may comprise a list of entity identifiers corresponding to each of a set of targeted entities extracted from the entity cohort file 402, their individual entity-level scores (e.g., scaled risk scores, scaled event scores), and/or a cohort score for the entity cohort. In addition, or alternatively, the compressed entity cohort file 404 may comprise one or more contextual score attributes, such as one or more assignable codes, and/or the like for each of the entities.

In this manner, the compressed entity cohort file 404 may comprise a compressed representation of the entity cohort file 402 that is transferable to the client device 410. The compressed nature of the compressed entity cohort file 404 allows for efficient storage and quick retrieval of key entity and cohort level information from a robust entity cohort file 402. It may be implemented as a structured data file, such as a CSV, JSON, or database table, optimized for rapid access and analysis. The entity-level scores within the compressed entity cohort file 404 may represent various metrics like risk scores, engagement probabilities, or quality measure gaps. The cohort score may be a composite metric reflecting the entity cohort performance across multiple domains. This condensed format enables end users to quickly access, identify, and prioritize entities within a robust dataset without processing large volumes of raw data.

In some embodiments, the compressed entity cohort file 404 is stored within the domain datastore 408 in association with a plurality of compressed entity cohort files respectively corresponding to a plurality of different entity cohorts. In this manner, the plurality of compressed entity cohort files may provide an accessible layer of entity data that may be selectively retrieved by a client device 410. By doing so, the compressed entity cohort files may enable user interfaces for navigating, prioritizing, and initiating actions for individual entities that are organized across a plurality of different entity cohorts and associated with robust, traditionally unobservable datasets.

In some embodiments, the data compression pipeline 406 enables a selection interface accessible through a client device 410. For example, the client device (and/or data compression pipeline 406) may initiate a presentation of a selection interface to a user that comprises a plurality of selectable icons respectively corresponding to a plurality of entity cohorts. To address the limited screen sizes of client devices 410, the entity cohorts may be represented by the compressed entity cohort files 404 of the domain datastore 408. For example, the selection interface may comprise a plurality of selectable icons that respectively correspond to the values of a compressed entity cohort file 404. In some examples, the plurality of selectable icons may be arranged within the selection interface based on the parameters of the compressed entity cohort file 404, such as the cohort score. By way of example, the plurality of selectable icons may be arranged in accordance with a magnitude of each of a plurality of cohort scores respectively corresponding to the plurality of entity cohorts as represented by their respective compressed entity cohort files.

In some embodiments, the selection interface is a user interface, accessible via a client device 410, that is configured for implementing downstream engagement actions based on a compressed entity cohort file 404. The selection interface serves as a bridge between the data compression pipeline and client devices that interact directly with entities in the real world. The interface may be implemented as a graphical user interface (GUI) accessible through web browsers, desktop applications, mobile applications, and/or the like. In some examples, the selection interface may present a ranked list of entities. The ranked list of entities, for example, may be provided based on the cohort score and/or one or more composite scores thereof (e.g., scaled risk scores, scaled event scores). In some examples, the selection interface may comprise interactive elements such as clickable rows, filter options, sorting capabilities, and/or the like to help users navigate and/or refine an entity list. During an engagement action, the interface may expand to offer different action types, such as medication adherence actions (for continuous events), screening procedures (for single events), testing actions (for monitoring events like blood pressure checks), and/or the like. In some examples, the selection interface may integrate with external robotic devices, such as medication delivery devices, automated injections patches, insulin delivery systems, and/or the like, to initiate medication delivery responsive to an engagement action initiated by the selection interface.

In some embodiments, the selection interface is modified based on location data of a user of the client device 410. For instance, the client device 410 may receive location data associated with a user of the selection interface and provide the location data to the domain datastore 408 (and/or a remote computing system associated therewith) with a request to access at least a portion of the entity cohorts. In some examples, the domain datastore 408 (and/or a remote computing system associated therewith) may identify a portion of the plurality of entity cohorts based on the location data and return the portion of the plurality of entity cohorts for display via the selection interface. In addition, or alternatively, the selection interface may identify a portion of a plurality of entity cohorts based on the location data and modify the selection interface to adjust a focus to the portion of the plurality of entity cohorts.

In some embodiments, the location data is geographical information associated with a user of the selection interface and/or one or more entities of an entity cohort that informs which entities may be assigned a downstream engagement action by a particular user and/or a type of engagement action for the particular user. The location data, for example, may comprise GPS coordinates, street addresses, zip codes, predefined geographical areas, and/or the like. In some examples, the location data may be stored in various formats, such as latitude/longitude pairs, geocoded addresses, geospatial database entries, and/or the like. In some examples, the location data may be used in conjunction with the selection interface and the compressed entity cohort file 404 to optimize member engagement strategies. For instance, the location data may be used to filter a ranked entity list to focus within a certain radius of a user's current location. In some examples, the selection interface may leverage one or more geospatial algorithms to generate travel times, optimal routes, and/or the like to identify a set of reachable entities within an operational time period.

FIG. 5 is a dataflow diagram 500 of a data compression technique in accordance with some embodiments of the present disclosure. As shown, the data compression technique may be implemented by a data compression pipeline 406. The data compression pipeline 406, for example, comprise one or more hardware and/or software components executed by one or more computing systems, devices, and/or the like to implement a series of data compression operations that compress an entity cohort file into a compressed entity cohort file. By doing so, the data compression pipeline 406 may improve the transferability, interpretability, and storage footprint for traditionally robust datasets. This may, in turn, improve data retrieval and processing times, while enabling improved user interfaces, such as the selection interfaces of the present disclosure, which may arrange, prioritize, and focus on portions of entities within a large, multi-cohort prediction domain based on holistic, entity-level parameters and in real time. These technical benefits may be achieved, through the data compression pipeline 406, by implementing a three stage, asynchronous, data processing pipeline in which a first predictive model 514, a second predictive model 516, and an optimization model may process a plurality of entity attributes 502 in parallel to convert the entity attributes 502 to a compressed entity cohort file 404.

In some embodiments, the data compression pipeline 406 receives an entity cohort file that identifies a plurality of entity attributes 502 for each entity within an entity cohort. The plurality of entity attributes 502 may comprise a first set of binary coded attributes 504, a second set of categorical attributes 506, and/or a third set of historical attributes 508 for an entity of the entity cohort. In some examples, the first set of binary coded attributes may correspond to a plurality of codes defined within a prediction domain. The second set of categorical attributes 506 may comprise a set of defined features within the prediction domain and the third set of historical attributes 508 may comprise a plurality of historical features associated with an entity.

In some embodiments, an entity attribute is a characteristic of an entity and may be one of three different types of attributes, including a binary coded attribute 504, a categorical attribute 506, or a historical attribute 508. An entity attribute may be an individual data point (e.g., feature value) associated with a particular entity within an entity cohort. As described herein, one or more sets of entity attributes 502 may be provided as inputs for various predictive models to generate one or more outputs of the present disclosure. By way of example, a plurality of entity attributes 502 may be represented as a feature vector for input to a predictive model. In some examples, each entity attribute may comprise an attribute value of a particular data type. For instance, a binary coded attribute 504 may comprise a binary value that identifies a presence and/or absence of a specific code. As another example, a categorical attribute 506 may comprise a categorical value that identifies a class of one or more defined classes for a particular categorical attribute. In addition, or alternatively, a historical attribute 508 may comprise an attribute value that may identify a number of historical occurrences, interactions, and/or context association with the number of historical occurrences as expressed in real numbers, textual data types, and/or the like. Together, a plurality of entity attributes 502 may provide a comprehensive profile (e.g., the entity cohort file) of each entity.

In some embodiments, the binary coded attribute 504 is a type of entity attribute that indicates whether an entity is associated with a code defined within a prediction domain. The code may depend on the prediction domain. For instance, in a clinical domain, a code may comprise a Hierarchical Condition Category (HCC) code. Other examples may comprise an error codes in a computing domain, and/or the like.

In some examples, a binary coded attribute 504 may comprise a binary unit within a binary vector that comprises a binary value for each of a set of defined codes (e.g., HCC codes). By way of example, the binary vector may comprise a series of binary values (e.g., 0 or 1) in which the position of value within the series corresponds to a particular code, where 1 indicates a presence of the particular code and 0 indicates its absence. In some examples, the binary vector may correspond to a particular time period. For instance, a binary vector may be reset (e.g., all values set to 0) at a predefined frequency (e.g., daily, monthly, yearly) and then updated as codes are identified for an entity during a defined time period within the predefined frequency. By way of example, a binary vector may be recoded on a yearly basis to enforce a yearly reassessment of an entity with respect to each of a plurality of defined codes. In the context of a healthcare domain, for example, the annual reset of the binary vector may ensure that a member's health status is regularly reevaluated, reflecting changes in their conditions over time.

In some embodiments, the categorical attribute 506 is a type of entity attribute that indicates one or more attribute classes of an entity that are defined within a prediction domain. The attribute classes may depend on the prediction domain. For instance, the attribute classes may define one or more demographic categories, such as gender, ethnicity, age band (e.g., 0-2, 3-6, 7-12, 13-18, 19-30), or other demographic classifications that may be used to categorize members of a population. Each categorical attribute 506 may comprise a discrete value that is represented as a distinct category or group. In some examples, categorical attributes 506 may be leveraged by various predictive models of the present disclosure to provide contextual data for one or more predictions. For example, as described herein, categorical attributes 506 may correspond to at least a portion of a graph-based model (e.g., graph-based causal model) in which one or more nodes of the model correspond to different classes of a categorical attribute 506. In this way, the categorical nature of a categorical attributes 506 may enable stratification and comparison of different subgroups within a population through graph traversals, among other techniques of the present disclosure.

A categorical attribute 506 may be encoded as a discrete variable in categorical vector for an entity. For instance, the categorical vector may be encoded from a set of categorical attribute values through one-hot encoding or label encoding to convert the values into a vectorized format to improve the storage, retrieval, and processing of the set of categorical attribute values. In some embodiments, categorical attribute values, and/or categorical vectors thereof, may be stored in an entity cohort file as enumerated types, as foreign keys referencing lookup tables containing the possible category values, and/or the like.

In some embodiments, the historical attribute 508 to a type of entity attribute that indicates one or more past observations and/or data points associated with an entity that may be used by one or more models of the present disclosure to generate predictions for the entity. A historical attribute 508, for example, may comprise one or more different data types that describe a historical recorded experience, behavior, or characteristic and/or the like that may be predictive within a particular prediction domain. By way of example, a historical attribute 508 may comprise an attribute value that may encompass a wide range of data types, including a count value (e.g., a number of clinical visits, claim submissions, hospital admissions), test result value (e.g., lab test results, performance measurements), text value (e.g., a claim description, lifestyle factors), engagement indicators (e.g., labels indicating whether an entity engaged), and/or the like, that are recorded over time. In some examples, the historical attribute 508 may provide a longitudinal view of an entity's historical behavior within a prediction domain.

In some examples, a plurality of historical attribute values for an entity may be stored as one or more historical attribute vectors, time-series databases, linked timestamped entries, and/or the like. The plurality of historical attribute values by stored within an entity cohort file and/or referenced by the entity cohort file. In some example, the historical attribute values may be preprocessed and aggregated to create derived features, such as frequency counts, averages over time periods, and/or other indicators extracted from a group of historical observations. In some examples, prediction models, such as machine learned models designed for sequential data (e.g., recurrent neural networks, temporal convolutional networks) may leverage the historical attribute values for a particular entity to generate one or more predictions.

In some embodiments, the data compression pipeline 406 extracts a cohort-level optimization dataset 510 from the entity cohort file that identifies a subset of target entities from the entity cohort. The subset of target entities may comprise a representative entity that is used in singular form herein to describe the operations performed for each entity within the entity cohort of the entity cohort file.

In some embodiments, the cohort-level optimization dataset 510 is an engineered feature dataset for an entity cohort file. The cohort-level optimization dataset 510, for example, may comprise a relational database, a graph database, and/or any other data structure configured to store a plurality of predictive features for an entity cohort. In some examples, at least a portion of the plurality of predictive features may be stored at an entity and/or feature level to allow for reusability of the predictive features for other optimization techniques. In this manner, the cohort-level optimization dataset 510 may reduce memory usage requirements for complex optimization tasks, while allowing access to at least a portion of the entity cohort file through client interfaces. In some examples, the cohort-level optimization dataset may comprise an intermediate representation of an entity cohort file that may be generated in accordance with one or more embodiments of U.S. patent application Ser. No. 18/958,625, which is incorporated by reference herein for all purposes.

In some examples, the cohort-level optimization dataset 510 may be received and/or identified from the entity cohort file. The cohort-level optimization data may be executed to generate a subset of entity data objects that identify a subset a target entities from the entity cohort file and a quality score corresponding to the target entities. By way of example, in a healthcare STAR ranking example, the subset a target entities may comprise a minimum number of entities (and/or STAR quality measures thereof) required to increase a STAR rating associated with the entity cohort. The quality score may comprise a predicted revenue increase due to the STAR increase.

In some embodiments, the data compression pipeline 406 generates, using a first predictive model 514, a scaled risk score 538 for the entity based on the first set of binary coded attributes 504. For example, the data compression pipeline 406 may generate, using a first branch 518 of the first predictive model 514, a plurality of code predictions 522 for the plurality of codes defined within a prediction domain, respectively. For instance, the data compression pipeline 406 may generate a code prediction 522 for each code of the plurality of codes.

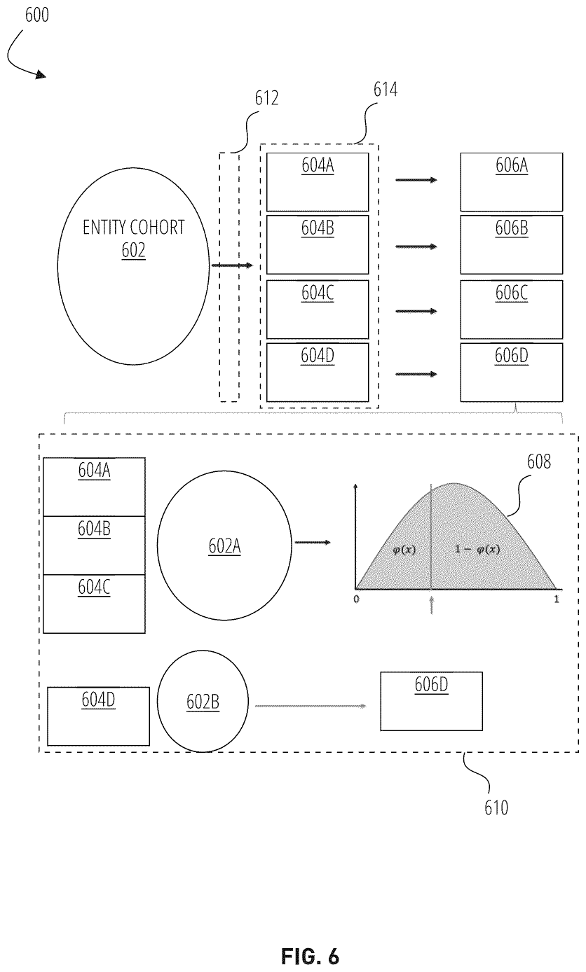

In some embodiments, the first predictive model 514 is a first sub-model pipeline implemented within the data compression pipeline 406. The first predictive model 514 may comprise a branched processing model architecture that defines a first branch 518, a second branch 520, an aggregation layer 526, and/or first scaling layer 528 configured to output the scaled risk score 538 for an entity. For example, the branched processing model architecture of the first predictive model 514 may define a plurality of interconnected components that collectively generate the scaled risk score 538 for the entity through a series of data transformations to different sets of entity attributes 502 associated with the entity. In some examples, as described in further detail with reference to FIG. 6, the first branch 518 of the first predictive model 514 may apply a model ensemble for an entity, on a code-by-code basis, to adaptively generate the code prediction 522 based on the first set of binary coded attributes 504 associated with the entity.

In addition, or alternatively, the data compression pipeline 406 may generate, using a second branch 520 of the first predictive model 514, a simulated engagement score 524 for the entity based the second set of categorical attributes 506. In some examples, the second branch 520 of the first predictive model 514 may comprise a simulation model configured to generate a simulated engagement score 524 for the entity. In some examples, the simulated engagement score 524 may be generated asynchronously with a plurality of code predictions 522 output by the first branch 518 of the first predictive model 514. In this manner, the first branch 518 and the second branch 520 of the first predictive model 514 may operate asynchronously to improve compression speeds for the entity cohort file. By way of example, the first predictive model 514 may be implemented using one or more combinations of hardware, software, and/or the like. For example, the first predictive model 514 may be executed by one or more processors in a distributed computing environment, with different components of the model executed on separate machines and/or in parallel for improved performance. The first predictive model 514 may be used in various prediction domains to combine rule-based and/or machine learned approaches to allow for a nuanced and accurate assessment of code-based risks across a wide range of different coding scenarios, including healthcare coding system, computer performance coding system, and/or the like.

In some embodiments, the simulation model is a portion of the second branch 520 of the first predictive model 514 that may be executed in parallel with the models of the first branch 518 of the first predictive model 514. The simulation model, for example, may comprise a second machine learned model that is trained to output a simulated engagement score 524 for an input entity. The simulation model may comprise any type of machine learned model, such as logistic regression, random forest, neural network, and/or the like. For example, the simulation model may comprise a supervised machine learning model, such as a machine learned regression model (e.g., linear regression, logistic regression, polynomial regression, ridge regression) that is trained to predict a simulated engagement score 524 based on at least a portion of the historical entity dataset. The portion of the historical entity dataset, for example, may comprise a plurality of labeled training entries, each comprising a plurality of historical attributes 508 and a ground truth label identifying a historical engagement of a historical entity. The historical engagement label, for example, may reflect a historical data that captures past entity interactions and engagement patterns with a computing system. The plurality of historical attributes 508 may comprise any attributes (e.g., communication preferences) that have a measured impact on engagement likelihood. In some examples, the training process may be adapted to one or more different historical attribute types to tailor the simulation model for different ranges of inputs (e.g., diagnoses, procedures, medications, lab results, demographic information in a healthcare example) for a particular domain.

The training process may comprise feeding the labeled training entries into the simulation model, which then learns (e.g., through backpropagation of errors) to map the input attributes to engagement outcomes. The trained simulation model may be configured to generate simulated engagement scores 524 for new, unseen entities. These predictions represent the probability that an entity will engage with a computing system. In some examples, the simulation model may also be periodically retrained and/or fine-tuned to adapt to changing engagement patterns over time.

In some embodiments, the simulated engagement score 524 is a probabilistic value that identifies a likelihood that an entity with participate with an initiative by a computing system. The simulated engagement score 524, for example, may comprise a numerical value between 0 and 1, where higher values indicate a greater likelihood of engagement. The simulated engagement score 524 may be generated by the simulation model based on one or more historical and/or categorical attributes of the entity.

In some embodiments, the data compression pipeline 406 generates, using an aggregation layer 526 of the first predictive model 514, a risk score for the entity based on an aggregation of the plurality of code predictions 522 and the simulated engagement score 524. In some examples, the aggregation layer 526 of the first predictive model 514 may be configured to receive the plurality of code predictions 522 and the simulated engagement score 524 for an entity from the first branch 518 and the second branch 520 of the first predictive model. The aggregation layer 526 may be configured to aggregate the plurality of code predictions 522 and the simulated engagement score 524 to generate an unscaled risk score for the entity. By way of example, the plurality of code predictions 522 may comprise a prediction (e.g., 0, 1, or value between 0 and 1) for each defined code within a prediction domain. The aggregation layer 526 may aggregate (e.g., through summation, mean, median) the plurality of code predictions 522 to generate an aggregated code prediction. The aggregation layer 526 may apply (e.g., through multiplication) the simulated engagement score 524 to the aggregated code prediction to generate the unscaled risk score.

In some embodiments, the risk score is an unscaled intermediate output of the first predictive model 514. The risk score may comprise a numerical score of a first data type that describes an opportunity of diagnosing an entity with one or more of a set of codes defined within a prediction domain. This risk score may comprise a standalone variable that is incompatible with other types of risk measurements, such as other intermediate outputs of the data compression pipeline 406.

The risk score may comprise an intermediate output of the first predictive model 514 that combines a plurality of rule-based and machine learned intermediate outputs into a single data value for each entity within an entity cohort of the entity cohort file. A risk score for an entity, for example, may be generated by the aggregation layer 526 of the first predictive model 514. The aggregation layer 526 is configured to receive (i) a plurality of normalized code predictions that respectively correspond to the plurality of codes defined within a prediction domain and (ii) the simulated engagement score 524 for the entity. The aggregation layer 526 may be configured to aggregate (e.g., sum) the plurality of normalized code predictions to generate an aggregated code prediction for the entity. In some examples, aggregating the plurality of code predictions may comprise identifying one or more hierarchical relationships between the codes. For instance, each code may correspond to plurality of codes may define one or more hierarchical relationships that prevent the assignment of two or more codes from the same hierarchical group to a single entity (e.g., if the constituent codes refer to different severities of the same underlying condition). To account for this, the aggregated code prediction may be determined for each hierarchy group R as mathematically expressed by:

$$R = min ( 1 , {\sum }_{k = 1}^{k = n} {r}^{k} ) ,$$

where r^{k} is the code prediction for code k where there are n codes in the code hierarchy. Conversely, if the constituent codes refer to independent conditions, then the risk opportunity per code hierarchy group may be expressed as follows:

$$R = 1 - {\prod }_{k = 1}^{k = n} ( 1 - {r}^{k} ) .$$

In some examples, the unscaled intermediate output may be generated by multiplying the aggregated code prediction with the simulated engagement score 524. In this manner, a first intermediate risk-based output may be generated for an entity within an entity cohort. The risk score may comprise a first data type that is distinct and incompatible with other risk measures for the entity. This means it cannot be directly combined or compared with other types of risk scores, such as those output by other portions of the data compression pipeline 406. This incompatibility ensures that the risk score maintains its specific interpretation and use within the data compression pipeline 406 but prevents further compression and data synthesis across component parts of the data compression pipeline 406. To address these technical challenges, the risk score may be transformed to a scaled risk score 538 using a subsequent, scaling layer of the first predictive model 514.

In some embodiments, the data compression pipeline 406 applies, using the first scaling layer 528 of the first predictive model 514, a first scaling coefficient 530 to the risk score to generate a scaled risk score 538. By way of example, the risk score may be a first data type that is different than the data types of one or more other intermediate outputs of the data compression pipeline 406, such as an event prediction of a second data type that is incompatible with the first data type. In some examples, the first scaling coefficient 530 may be defined by a compatibility ruleset for transforming the first data type to a compatible data type for aggregation with other intermediate outputs of the data compression pipeline 406.

In some examples, the first scaling layer 528 may be configured to covert the unscaled risk score to a scaled risk score 538 to enforce data type compatibility across different intermediate outputs of the data compression pipeline 406. For instance, the first scaling layer 528 may apply a first scaling coefficient 530 to the unscaled risk score to generate a scaled risk score 538. The first scaling coefficient 530 may be configured to transform the unscaled risk score of a first data type (e.g., risk type) to a scaled risk score 538 of a compatible data type (e.g., reward type) that is compatible with other intermediate outputs of the data compression pipeline 406. The first predictive model 514 may output the scaled risk score 538 to one or more downstream models of the data compression pipeline 406.

The scaled risk score 538 may be a transformation of a risk score for an entity from a first data type to a compatible data type that may be synthesized with other intermediate outputs of the data compression pipeline 406. The transformation process may be performed by the first scaling layer 528 of the first predictive model 514 by applying (e.g., multiplying) the first scaling coefficient 530 to the risk score. By doing so, the risk score, which is initially in a standalone, incompatible format, may be integrated with other types of data for comprehensive data synthesis and compression.

In some embodiments, the first scaling coefficient 530 is a data value that describes a scaling parameter for converting a risk score from a first data type to a compatible data type that may be combined with other compatible data types. The first scaling coefficient 530, for example, may transform an abstract, standalone, risk measurement to an actionable, concrete metric that is measurable in the real world. For instance, the first scaling coefficient 530 may comprise a unit of measurement defined within a prediction domain to measure a value (e.g., financial value, time value, processing value) of a particular service. By way of example, in a healthcare example, the first scaling coefficient 530 may represent an average and/or expected revenue associated with the assignment of a new code to an entity to manage a particular condition or set of conditions corresponding to a plurality of codes. The first scaling coefficient 530, for example, may be set based on an average reimbursement rate, historical patterns of healthcare utilization, average member costs, and/or the like, to transform a level of risk, as represented by a risk score, to a financial value of the level of risk, as represented by the scaled risk score 538.

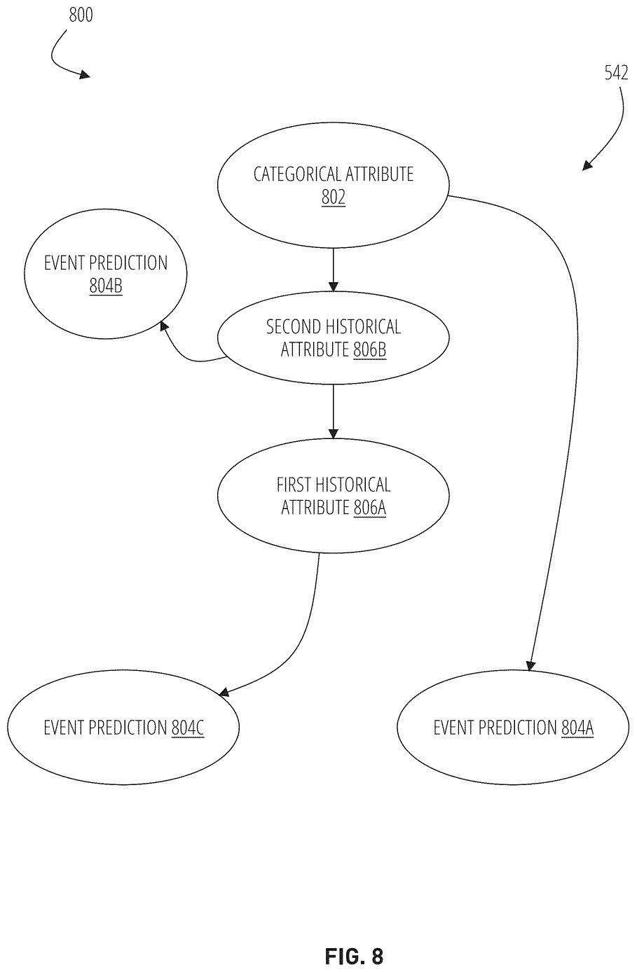

In some embodiments, the data compression pipeline 406 generates, using a second predictive model 516, a scaled event score 540 for the entity based on the second set of categorical attributes 506. In some examples, the second predictive model 516 may comprise a second sub-model pipeline within the data compression pipeline 406. The second predictive model 516 may comprise a graph-based causal model 542 and a second scaling layer 546. The graph-based causal model 542, for example, may be used to identify an event prediction 544 for an entity based on the categorical attributes 506 and/or historical attributes 508. For instance, the graph-based causal model 542 may comprise a plurality of nodes that correspond to the second set of categorical attributes 506 and/or the third set of historical attributes 508, an example of which is described with reference to FIG. 8. In this manner, the second predictive model 516 may be designed to capture complex relationships and causal pathways expressed by entity attributes, particularly focusing on predicting future events within a prediction domain, such as hospital admissions in a clinical domain.

In some examples, the second predictive model may comprise a second scaling layer 546 to transform the event prediction 544 to a scaled event score 540 that may be combined with the other intermediate outputs of the data compression pipeline 406. For example, the data compression pipeline 406 may generate, using the graph-based causal model 542, an event prediction 544 for the entity based on the second set of categorical attributes 506 and/or the third set of historical attributes 508. The data compression pipeline 406 may apply, using a second scaling layer 546, a second scaling coefficient 548 to the event prediction 544 to generate the scaled event score 540. In some examples, the event prediction may be a second data type that is different than the data types of one or more other intermediate outputs of the data compression pipeline 406, such as the risk score of a first data type incompatible with the second data type. The second scaling coefficient 548 may be defined by a compatibility ruleset for transforming the second data type to a compatible data type for aggregation with other intermediate outputs of the data compression pipeline 406.

To generate the event prediction 544, the second predictive model 516 may input a plurality of categorical attributes (e.g., age group, gender) and/or historical attributes (e.g., past hospitalizations, treatment history) to the graph-based causal model 542. The graph-based causal model 542 may propagate the inputs through the graph structure (e.g., via graph traversal techniques, such as depth first search (DFS), breath first search (BFS)) to generate the event prediction 544. In some examples, the second predictive model 516 may enable an interpretable output, for example, the causal structure of the model may be visualized, recorded, and/or output with the event prediction to provide contextual data (e.g., explainability) for the event prediction.

The event prediction 544 may comprise an unscaled intermediate output of the second predictive model 516. The event prediction 544 may comprise a numerical score of a second data type that describes an admission risk (e.g., a hospital admission risk in a clinical context) for an entity within a prediction domain. This event prediction 544 may comprise a standalone variable that is incompatible with other types of risk measurements, such as other intermediate outputs of the data compression pipeline 406. The event prediction 544 may be generated for each entity within an entity cohort of an entity cohort file using the graph-based causal model 542. Each event prediction 544 may comprise the same data type that is distinct from other risk measures. This ensures that it maintains its specific interpretation within the context of a data compression pipeline 406 but prevents further compression and data synthesis across component parts of the data compression pipeline 406. To address these technical challenges, the event prediction 544 may be transformed to a scaled event score 540 using a subsequent, second scaling layer 546 of the second predictive model 516.

In some embodiments, the scaled event score 540 is a transformation of an event prediction 544 for an entity from a second data type to a compatible data type that may be synthesized with other intermediate outputs of a data compression pipeline 406. The transformation process may be performed by the second scaling layer 546 of the second predictive model 516 by applying (e.g., multiplying) a second scaling coefficient 548 to the event prediction 544. By doing so, the event prediction 544, which is initially in a standalone, incompatible format, may be integrated with other types of data for comprehensive data synthesis and compression.

In some embodiments, the second scaling coefficient 548 is a data value that describes a scaling parameter for converting an event score from a second data type to a compatible data type that may be combined with other compatible data types. The second scaling coefficient 548, for example, may transform an abstract, standalone, event measurement to an actionable, concrete metric that is measurable in the real world. For instance, the second scaling coefficient 548 may comprise a unit of measurement defined within a prediction domain to measure a value (e.g., financial value, time value, processing value) of a particular service. By way of example, in a healthcare example, the second scaling coefficient 548 may represent an average and/or expected cost associated with a hospital admission. The second scaling coefficient 548, for example, may be set based on an average monetary cost per admission, and/or the like, to transform a causal reduction in a number of hospital admissions, as represented by an event prediction 544, to a financial value of the causal reduction in a number of hospital admissions, as represented by the scaled event score 540.

In some embodiments, the data compression pipeline 406 generates a cohort score for the entity cohort file based on the scaled risk score 538, the scaled event score 540, and/or the subset of target entities of the cohort-level optimization dataset 510. The cohort score, for example, may be generated, using the data compression pipeline 406, through a multi-stage process that leverages the plurality of predictive models and scaling techniques to synthesize outputs from the plurality of predictive models. For example, in a first stage, individual entity-level scores may be generated, including the scaled risk scores 538 and scaled event scores 540. At a second stage, these scores may be aggregated across all entities (and/or a subset thereof) in the cohort to generate cohort-level scores for the entity cohort. At a third stage, the cohort-level scores may be synthesized with a quality score to generate the cohort score. In this manner, an entity cohort file may be represented by a single, transferable value that may be stored, transferred, and displayed in place of the entity cohort file.

In some embodiments, the cohort risk score is an aggregated score for an entity cohort that is used to compress an entity cohort file into a single value. The cohort score, for example, may synthesize the scaled intermediate outputs from the first predictive model 514 and the second predictive model of the data compression pipeline 406 to generate a comprehensive assessment of the entity cohort file. In some examples, the cohort score may comprise an aggregated value that comprises an aggregation (e.g., a summation) of at least a subset of the scaled risk scores 538 and/or the scaled event scores 540 corresponding to at least a subset of the entities of the entity cohort. By way of example, the subset of the scaled risk scores 538 and/or the scaled event scores 540 may comprise the scaled risk score 538 and scaled event score 540 for each of a subset of target entities identified within a cohort-level optimization dataset 510. In some examples, the cohort score may comprise an aggregation (e.g., summation) of the subset of the scaled risk scores 538 and/or the scaled event scores 540 and a quality score corresponding to the cohort-level optimization dataset 510.

In some embodiments, the data compression pipeline 406 stores a compressed entity cohort file that identifies the cohort score, the subset of target entities, and an entity-level score (e.g., scaled risk score 538, scaled event score 540) for each entity within the subset of target entities, as described herein.

FIG. 6 is an operational example 600 of a first branch of the first predictive model in accordance with some embodiments of the present disclosure. As shown in the operational example 600, the first branch of the first predictive model may comprise routing logic 612, a model ensemble 614, and a normalization layer 610. In some examples, the model ensemble 614 may comprise one or more rule-based risk prediction models 604A-C and/or a machine learned risk prediction model 604D that are selectively executed for a particular entity of an entity cohort 602 using the routing logic 612 configured to route entities from an entity cohort 602 to different models of the model ensemble 614. In some examples, the normalization layer 610 may comprise a terminating layer of the machine-learned risk prediction model 604D configured to normalize the prediction output 606D from the machine learned risk prediction model 604D.

In some embodiments, the first branch 518 of the first predictive model 514 may comprise first, rule-based risk prediction models 604A-C that assigns a binary value to an entity for a particular code based on the entity's attributes (e.g., binary coded attributes 504, categorical attributes 506, historical attributes 508) and/or satisfaction of rule-based criteria (e.g., decision trees). For example, the first, rule-based risk prediction models 604A-C may assign a first binary value (e.g., “1”) if a binary coded attribute comprises the first binary value, one or more historical attributes satisfy a rule-based criteria defined for a particular code, and/or the like. The first rule-based risk prediction models 604A-C may assign a second binary value (e.g., “0”) otherwise. In addition or alternatively, the first branch 518 of the first predictive model 514 may comprise a second, machine-learned risk prediction model 604D that outputs a predicted probability of a particular code. This component may utilize advanced machine learning techniques, such as a Reverse Time Attention (RETAIN) model, and/or the like, to analyze an entity's attributes and predict the code prediction (e.g., between 0 and 1) for a particular code.

In some embodiments, the first branch of the first predictive model may comprise a routing logic 612 to route an entity (and/or entity attributes thereof) between the different models within first branch. The routing logic 612, for example, may comprise one or more hardware and/or software logic gates configured to route an entity between different models within the first branch of the first predictive model. For instance, the routing logic may comprise conditional logic that routes an entity between the different models based on one or more defined conditions. The defined conditions, for example, may comprise a first conditional statement configured to route an entity to a first rule-based risk prediction model (e.g., an active ruleset 604A) for a particular code if the entity has a binary coded attribute value (e.g., 1) already assigned for the particular code, a second conditional statement configured to route an entity to a second rule-based risk prediction model (e.g., an inference ruleset 604B) for a particular code if one or more historical attributes and/or categorical attributes satisfy a rule-based decision tree that identifies a rule-based assignment for the particular code, and/or a third conditional statement configured to route an entity to a third rule-based risk prediction model (e.g., a recapture ruleset 604C) for a particular code if a historical attribute identifies a historical assignment of a binary coded attribute value (e.g., 1) for the particular code and the particular code is classified as a reoccurring code. In addition, or alternatively, the defined conditions may comprise a fourth conditional statement configured to route the entity to a machine learned risk prediction model 604D if the none of the first, second, or third conditional statements are satisfied. In this way, different portions of the first predictive model may be selectively applied to an entity to generate a binary value for a binary coded attribute based on the characteristics of the entity.

For example, for each code-entity pair (e.g., a particular code from a plurality of defined codes for an entity) of the entity cohort 602, the first branch may be configured to determine, using the routing logic 612, a processing route for the code. Responsive to the processing route identifying one of the rule-based risk prediction models 604A-C, the first branch may input a first set of binary coded attributes and/or the third set of historical attributes for the entity to the one of the rule-based risk prediction models 604A-C to receive a code prediction 606A-C for the entity with respect to the particular code. Responsive to the processing route identifying the machine learned risk prediction model 604D, the first branch may input a third set of historical attributes for the entity to the machine learned risk prediction model 604D to receive a code prediction 606D for the entity with respect to the particular code.

In some embodiments, the rule-based risk prediction models 604A-C comprise models within the first branch of the first predictive model that assign a binary value (e.g., 0 or 1) for a binary coded attribute based on a set of defined rules. The rule-based risk prediction models 604A-C, for example, may leverage different sets of predefined criteria to make deterministic decisions about an entity with respect to a particular code. The rule-based risk prediction models 604A-C may comprise three conditional rulesets, an active ruleset 604A, an inference ruleset 604B, and a recapture ruleset 604C. The active ruleset 604A may assign a “1” for a particular code if an entity is currently assigned a “1” for the specific code, and a “0” otherwise. The inference ruleset 604B may assign a “1” for a particular code if an entity's historical and/or categorical attributes satisfy a set of inference criteria that identifies entities that are likely to have a code but have not been explicitly assigned the code within a particular time period. The inference ruleset 604B, for example, may comprise a decision tree, a set of conditional statements, and/or the like. A recapture ruleset 604C may assign a “1” for a particular code if an entity's historical attributes identify a historical code assignment and the particular code is classified as a reoccurring code (e.g., a chronic condition).

The rule-based risk prediction models 604A-C may comprise one or more decision trees, series of conditional statements, and/or the like. In some examples, the series of condition statements may comprise if-then logic statements and a query to retrieve an entity attribute (e.g., from the entity cohort file) that corresponds to the if-then statement. In this manner, the rule-based risk prediction models 604A-C may define a plurality of conditional operations that is configured to extract data from the entity cohort file to generate a code prediction 606A-C for an entity with respect to a code. The rule-based risk prediction models 604A-C provide an interpretable and processing resource friendly approach to risk prediction but are less flexible than machine learned prediction approaches. By implementing the routing logic 612, the first branch of the first prediction model may balance the processing load of code predictions on a code-level to improve computing performance in complex coding spaces.

In some embodiments, the machine-learned risk prediction model 604D is a model within a first branch of the first predictive model that assigns a probability value (e.g., between 0 and 1) for a binary coded attribute using a machine learned network. The machine-learned risk prediction model 604D, for example, may be trained to capture complex patterns and relationships in historical and/or categorical attributes that are not defined by the rule-based risk prediction models 604A-C. The machine-learned risk prediction model 604D may comprise any combination of supervised, unsupervised, semi-supervised, reinforcement learning models, and/or the like. For instance, the machine-learned risk prediction model 604D may comprise a supervised machine learning model, such as a recurrent neural network. In some examples, the machine-learned risk prediction model 604D may comprise a Reverse Time Attention (RETAIN) model, such as the RETAIN model described in Choi et al. (2016), RETAIN: An Interpretable Predictive Model for Healthcare using Reverse Time Attention Mechanism, that is configured to processes a time series of historical attributes in reverse chronological order, giving more weight to recent entity attributes while still considering the entire time series of historical attributes.

In some examples, the machine-learned risk prediction model 604D is trained (e.g., via backpropagation or errors using gradient decent) on a historical entity dataset comprising a plurality labeled training entries, each comprising a plurality of historical attributes and a ground truth label identifying the presence of a particular code. In some examples, the training process may be adapted to one or more different historical attribute types to tailor the machine-learned risk prediction model 604D for different ranges of inputs (e.g., diagnoses, procedures, medications, lab results, demographic information in a healthcare example) for a particular domain. In addition, or alternatively, machine-learned risk prediction model 604D may comprise an ensemble of different neural networks, each trained for a specific code. To do so, during training, each neural network may be trained using a subset of the plurality of labeled training entries with labels that correspond to a one code of the plurality of codes defined within a prediction domain. In this way, each network of the machine-learned risk prediction model 604D may output a probability score for a particular code of the plurality of codes within the prediction domain based on the same set of input attributes. By way of example, the machine-learned risk prediction model 604D (and/or a network thereof) may output a code prediction 606D in the form of a probabilistic output.

In some examples, the machine-learned risk prediction model 604D may comprise a normalization layer configured to normalize the probabilistic output based on a code prediction distribution 608 for the entity cohort 602. For example, the first branch 518 may normalize the code prediction 606D based on a code prediction distribution 608 comprising a respective code prediction for each entity within the entity cohort 602. In some examples, the code prediction distribution 608 may comprise a code prediction 606D for each entity within a first cohort subset 602A that qualifies for one of the rule-based risk prediction models 604A-C, such that each entity within a second cohort subset 602B that qualifies for the machine-learned risk prediction model 604D may be normalized with respect to the first cohort subset 602A.

In some embodiments, the code prediction distribution 608 comprises a distribution of code predictions 606D for each entity within an entity cohort 602 (and/or entity subset 602A) with respect to a particular code. In some examples, the code prediction distribution 608 may be leveraged to normalize a code prediction 606D output by the machine-learned risk prediction model 604A with respect to a subset of entities 602A within the entity cohort 602 (e.g., the entities that were routed to a rule-based risk prediction model 604A-C). The code prediction distribution 608 may be generated by applying the machine-learned risk prediction model 604D to all members in the entity cohort 602. For example, a code-specific code prediction distribution may be generated for each code defined within a prediction domain by generating a code prediction 606D for each entity with respect to each code. The plurality of code predictions may be represented as a statistical distribution, such as a histogram, a cumulative distribution function, and/or the like that may be stored in a database and/or computed on-the-fly as needed by the normalization layer 610.

The code prediction distribution 608 may be leveraged to normalize a code prediction 606D output by the machine-learned risk prediction model 604D for an entity (e.g., from cohort subset 602B) routed to the machine-learned risk prediction model 604D with a plurality of code predictions for entities (e.g., from cohort subset 602A) that were not routed to the machine-learned risk prediction model 604D. By doing so, the first predictive model may combine rule-based and machine learned techniques, executed separately, without skewing the results of either process. This enables improved code predictions that are more interpretable in view of the overall distribution within the cohort. Moreover, the code prediction distribution 608 may be used to set one or more thresholds for risk categorization. For instance, the code prediction distribution 608 may be leveraged to identify a binary assignment threshold (e.g., a lower quartile of the distribution) that may be applied to code prediction 606D to transform the code prediction 604 from a probabilistic value to a binary value. By way of example, a code prediction 606D that meets or exceeds the binary assignment threshold may be transformed to a “1,” otherwise the code prediction 606D may be transformed to a “0.”

In some embodiments, the code prediction distribution 608 is used to normalize a code prediction output by the machine learned risk prediction model 604D from a probabilistic value that an entity has the underlying condition corresponding to code to a probabilistic value that the entity will be assigned the code if evaluated for the underlying condition. To do so, the code prediction may be estimated as the cumulative probability of the normalized code predictions of the code prediction distribution φ(x), where the distribution is defined for all entities that fit into the rule-based prediction model (e.g., an active ruleset, an inference ruleset, and recapture ruleset) in which it is determined that the entity had the underlying health condition. Here x denotes the entity's probabilistic code prediction output, with 0≤φ(x)≤1 and 0≤x≤1.

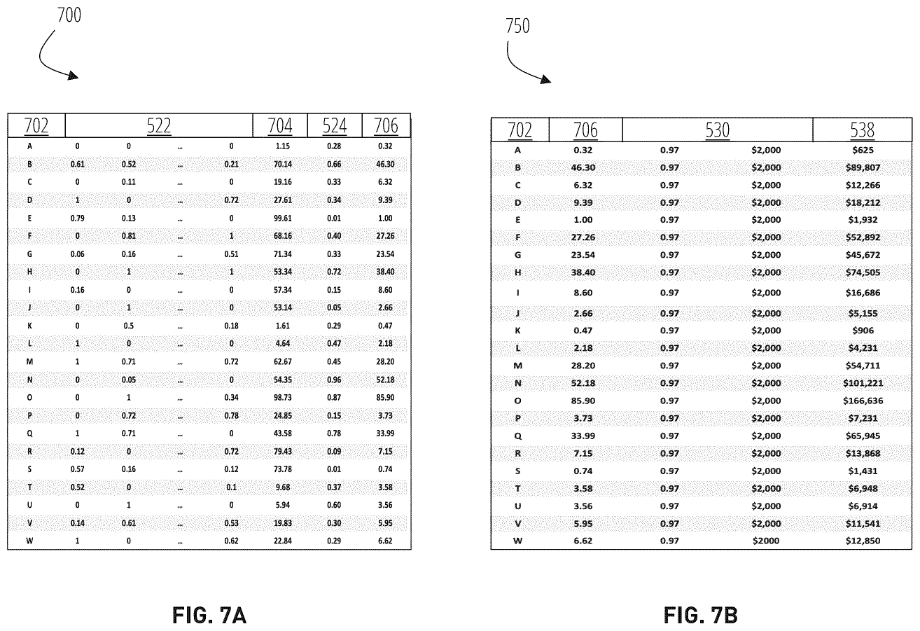

FIGS. 7A-B are an operational examples of a first predictive model outputs in accordance with some embodiments of the present disclosure. For example, FIG. 7A depicts an operational example 700 of the intermediate outputs of the first predictive model. FIG. 7B depicts an operational example 750 of the final outputs of the first predictive model.

As depicted by the operational example 700, a plurality of intermediate outputs for a plurality of entities 702 may comprise, for each entity, may comprise a code prediction 522 for each defined code within a prediction domain, an aggregated code prediction 704 that comprises an aggregation (e.g., summation) of each of the code predictions 522, a simulated engagement score 524, and a risk score 706 comprising an aggregation of the aggregated code prediction 704 and the simulated engagement score 524.

As depicted by the operational example 750, a plurality of final outputs for the plurality of entities 702 may comprise, the risk score 706, the first scaling coefficient 530, and the scaled risk score 538 comprising the risk score 706 scaled by the first scaling coefficient 530.

FIG. 8 is an operational example 800 of a graph-based causal model architecture in accordance with some embodiments of the present disclosure. As shown by the operational example 800, the graph-based causal model 542 may comprise graph structure, such as a directed acyclic graph (DAG), a probabilistic graphical model, a graph-based machine learned model, and/or the like, with a plurality of nodes and edges that represent relationships between various attributes that may influence an event of interest. By way of example, the graph-based causal model 542 may comprise a plurality of nodes, each representing different entity attributes and/or events. The nodes, for example, may comprise a categorical attribute 802, a first historical attribute 806A, a second historical attribute 806B, and/or the like. In addition, or alternatively, the graph-based causal model 542 may comprise a plurality of edges, each representing causal relationships or influences between a pair of nodes (e.g., entity attributes). The graph-based causal model 542 may comprise a plurality of terminating nodes representing different events, such as the event predictions 804A-C, that may be reached by traversing the intermediate nodes of the graph-based causal model 542.

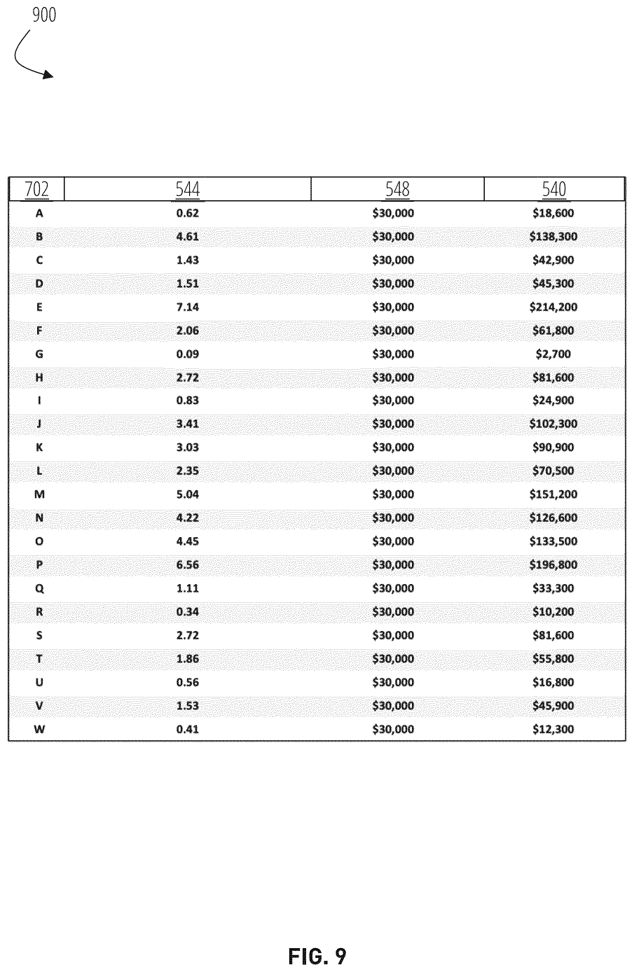

FIG. 9 is an operational example 900 of a second predictive model output in accordance with some embodiments of the present disclosure. As depicted by the operational example 900, a plurality of outputs for a plurality of entities 702 may comprise, for each entity, may comprise an event prediction 544, a second scaling coefficient 548, and a scaled event score 540 comprising the risk score 706 scaled by the second scaling coefficient 548.

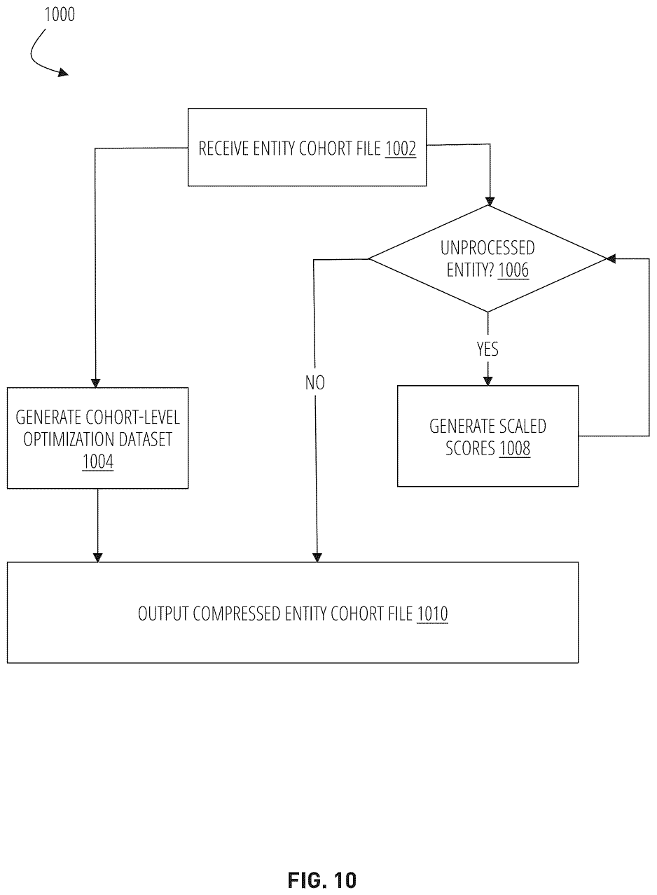

FIG. 10 is a flowchart diagram of an example data compression process 1000 in accordance with some embodiments of the present disclosure. The flowchart diagram depicts a data compression pipeline to improve the compression of a multi-factored dataset to reduce the file size of the dataset without information loss. The process 1000 may be implemented by one or more computing devices, entities, and/or systems described herein. For example, via the various steps/operations of the process 1000, the computing system 101 may synthesize intermediate outputs from a plurality of different processing pipelines, in parallel, to convert traditionally incompatible data types to a combinable counterparts. By doing so, the process 1000 improves computer functionality by improving data retrieval rates and data storage requirements for traditionally large datasets.

FIG. 10 illustrates an example process 1000 for explanatory purposes. Although the example process 1000 depicts a particular sequence of steps/operations, the sequence may be altered without departing from the scope of the present disclosure. For example, some of the steps/operations depicted may be performed in parallel or in a different sequence that does not materially impact the function of the process 1000. In other examples, different components of an example device or system that implements the process 1000 may perform functions at substantially the same time or in a specific sequence.

In some embodiments, the process 1000 comprises, at step/operation 1002, receiving an entity cohort file. For example, the computing system 101 may receive an entity cohort file that identifies a plurality of entity attributes for an entity within an entity cohort. The plurality of attributes may comprise a first set of binary coded attributes and a second set of categorical attributes.

In some embodiments, the process 1000 comprises, at step/operation 1004, generating a cohort-level optimization dataset. For example, the computing system 101 may extract a cohort-level optimization dataset from the entity cohort file that identifies a subset of target entities from the entity cohort that comprises the entity.

In some embodiments, the process 1000 comprises, at step/operation 1006, identifying an unprocessed entity from the entity cohort file. For example, the computing system 101 may identify the unprocessed entity. In the event that an unprocessed entity is present within the entity cohort file, the process 1000 may proceed to step/operation 1008, where one or more scaled scores are generated for the entity. Otherwise, the process 1000 may proceed to step/operation 1010, where a compressed entity cohort file may be output.

In some embodiments, the process 1000 comprises, at step/operation 1008, generating one or more scaled scores for the entity. For example, the computing system 101 may generate, using a first predictive model, a scaled risk score for the entity based on the first set of binary coded attributes. The computing system 101 may generate, using a second predictive model, a scaled event score for the entity based on the second set of categorical attributes.

In some embodiments, the first set of binary coded attributes correspond to a plurality of codes defined within a coding domain. The computing system 101 may generate, using a first branch of the first predictive model, a plurality of code predictions for the plurality of codes, respectively. For example, the first branch of the first predictive model may comprise a model ensemble that comprises a rule-based risk prediction model, a machine learned risk prediction model, and routing logic. The computing system 101 may determine, using the routing logic, a processing route for the code and, responsive to the processing route identifying the machine learned prediction model, input a third set of historical attributes for the entity to the machine learned prediction model to receive the code prediction. In some examples, the first branch of the first predictive model may comprise a normalization layer and the computing system 101 may normalize the code prediction based on a code prediction distribution comprising a respective code prediction for each entity within the entity cohort.

The computing system 101 may generate, using a second branch of the first predictive model, a simulated engagement score for the entity based the second set of categorical attributes. The computing system 101 may generate, using an aggregation layer of the first predictive model, a risk score for the entity based on an aggregation of the plurality of code predictions and the simulated engagement score. The computing system 101 may apply, using a scaling layer of the first predictive model, a first scaling coefficient to the risk score to generate the scaled risk score.

The computing system 101 may generate, using the second predictive model, an event prediction for the entity based on the second set of categorical attributes. The computing system 101 may apply a second scaling coefficient to the event prediction to generate the scaled event score. In some examples, the second predictive model may comprise a graph-based causal model with a plurality of nodes that correspond to the second set of categorical attributes. In some examples, the risk score is a first data type, and the event score is a second data type that is incompatible with the first data type, and the first scaling coefficient and the second scaling coefficient may be defined by a compatibility ruleset for transforming the first data type and the second data type to a compatible data type.

In some embodiments, the process 1000 comprises, at step/operation 1010, outputting a compressed entity cohort file for the entity cohort file. For example, the computing system 101 may generate a cohort score for the entity cohort file based on the scaled risk score, the scaled event score, and the subset of target entities. The computing system 101 may store the compressed entity cohort file that identifies the cohort score, the subset of target entities, and an entity-level score for each entity within the subset of target entities. In some examples, the compressed entity cohort file may be stored in association with a plurality of compressed entity cohort files respectively corresponding to a plurality of entity cohorts. The computing system 101 may initiate a presentation of a selection interface to a user that comprises a plurality of selectable icons respectively corresponding to the plurality of entity cohorts. In some examples, the computing system 101 may receive location data associated with a user of the selection interface, identify a portion of the plurality of entity cohorts based on the location data, and modify the selection interface to adjust a focus to the portion of the plurality of entity cohorts. In addition, or alternatively, the computing system 101 may arrange the plurality of selectable icons within the selection interface based on the cohort score. The plurality of selectable icons may be arranged in accordance with a magnitude of each of a plurality of cohort scores respectively corresponding to the plurality of entity cohorts.

Some techniques of the present disclosure enable the generation of action outputs that may be performed to initiate one or more real world actions to achieve real-world effects. The techniques of the present disclosure may be used, applied, and/or otherwise leveraged to generate a compressed entity cohort file that is accessible to small hardware packages. In some examples, the compressed entity cohort file may comprise entity-level and cohort predictions that may trigger action outputs (e.g., through control instructions) to automate communications between an entity and a provider and/or automate physical actions on behalf of the entity and/or provider. The action outputs may control various aspects of a client device, such as the display, transmission, and/or the like of data reflective of an alert, and/or the like. The alert may be automatically communicated to a user and/or may be used to initiate a security protocol (e.g., locking a computer), a robotic action (e.g., performing an automated screening process), an administration of a medication (e.g., an administration of an insulin injection by controlling an insulin delivery system based on a risk score), and/or the like.

In some examples, the computing tasks may comprise actions that may be based on a particular domain. A domain may comprise any environment in which computing systems may be applied to interpret, store, and process data and initiate the performance of computing tasks responsive to the data. These actions may cause real-world changes, for example, by controlling a hardware component, providing alerts, interactive actions, and/or the like. For instance, actions may comprise the initiation of automated instructions across and between devices, automated notifications, automated scheduling operations, automated precautionary actions, automated security actions, automated data processing actions, and/or the like.

### IV. CONCLUSION

Throughout this specification, components, operations, or structures described as a single instance may be implemented as multiple instances. Although individual operations of one or more methods (or processes, techniques, routines, etc.) are illustrated and described as separate operations, two or more of the individual operations may be performed concurrently or otherwise in parallel, and nothing requires that the operations be performed in the order illustrated. Structures and functionality (e.g., operations, steps, blocks) presented as separate components in example configurations may be implemented as a combined structure, functionality, or component. Similarly, structures and functionality presented as a single component may be implemented as separate components. These and other variations, modifications, additions, and improvements fall within the scope of the subject matter herein.

Certain embodiments are described herein as including logic or a number of routines, subroutines, applications, operations, blocks, or instructions. These may constitute and/or be implemented by software (e.g., code embodied on a non-transitory, machine-readable medium), hardware, or a combination thereof. In hardware, the routines, etc., may represent tangible units capable of performing certain operations and may be configured or arranged in a certain manner. In example embodiments, one or more computer systems (e.g., a standalone, client or server computer system) or one or more hardware modules of a computer system (e.g., a processor or a group of processors) may be configured by software (e.g., an application or application portion) as a hardware component that operates to perform certain operations as described herein.

In various embodiments, a hardware component may be implemented mechanically or electronically. For example, a hardware component may comprise dedicated circuitry or logic that is permanently configured (e.g., as a special-purpose processor, such as a field programmable gate array (FPGA) or an application-specific integrated circuit (ASIC)) to perform certain operations. A hardware component may also or instead comprise programmable logic or circuitry (e.g., as encompassed within one or more general-purpose processors and/or other programmable processor(s)) that is temporarily configured by software to perform certain operations.

Accordingly, the term “hardware component” should be understood to encompass a tangible entity, be that an entity that is physically constructed, permanently configured (e.g., hardwired), or temporarily configured (e.g., programmed) to operate in a certain manner or to perform certain operations described herein. Considering embodiments in which hardware components are temporarily configured (e.g., programmed), each of the hardware components need not be configured or instantiated at any one instance in time. For example, where the hardware components comprises a general-purpose processor configured using software, the general-purpose processor may be configured as respective different hardware components at different times. Software may accordingly configure a processor, for example, to constitute a particular hardware component at one instance of time and to constitute a different hardware component at a different instance of time.

Hardware components may provide information to, and receive information from, other hardware components. Accordingly, the described hardware components may be regarded as being communicatively coupled. Where multiple of such hardware components exist contemporaneously, communications may be achieved through signal transmission (e.g., over appropriate circuits and buses) that connect the hardware components. In embodiments in which multiple hardware components are configured or instantiated at different times, communications between such hardware components may be achieved, for example, through the storage and retrieval of information in memory structures to which the multiple hardware components have access. For example, one hardware component may perform an operation and store the output of that operation in a memory device to which it is communicatively coupled. A further hardware component may then, at a later time, access the memory device to retrieve and process the stored output. Hardware components may also initiate communications with input or output devices, and may operate on a resource (e.g., a collection of information).

As noted above, the various operations of example methods (or processes, techniques, routines, etc.) described herein may be performed, at least partially, by one or more processors that are temporarily configured (e.g., by software) or permanently configured to perform the relevant operations. Whether temporarily or permanently configured, such processors may constitute processor-implemented components that operate to perform one or more operations or functions. The components referred to herein may, in some example embodiments, comprise processor-implemented components.

Moreover, each operation of processes illustrated as logical flow graphs may represent a sequence of operations that may be implemented in hardware, software, or a combination thereof. In the context of software, the operations represent computer-executable instructions stored on one or more computer-readable storage media that, when executed by one or more processors, perform the recited operations. Generally, computer-executable instructions comprise routines, programs, objects, components, data structures, and the like that perform particular functions or implement particular data types. The order in which the operations are described is not intended to be construed as a limitation, and any number of the described operations may be combined in any order and/or in parallel to implement the processes.

The terms “coupled” and “connected,” along with their derivatives, may be used. In particular embodiments, “connected” may be used to indicate that two or more elements are in direct physical or electrical contact with each other, although the context in the description may dictate otherwise when it is apparent that two or more elements are not in direct physical or electrical contact. “Coupled” may mean that two or more elements are in direct physical or electrical contact. However, “coupled” may also mean that two or more elements are not in direct contact with each other, yet still co-operate, transmit between, or interact with each other.

An algorithm may be considered to be a self-consistent sequence of acts or operations leading to a desired result. These comprise physical manipulations of physical quantities. Usually, though not necessarily, these quantities take the form of electrical, magnetic, or optical signals capable of being stored, transferred, combined, compared, and otherwise manipulated. These signals are commonly referred to as bits, values, elements, symbols, characters, terms, numbers, flags, or the like. It should be understood, however, that all of these and similar terms are to be associated with the appropriate physical quantities and are merely convenient labels applied to these quantities.

Unless specifically stated otherwise, discussions herein using words such as “processing,” “computing,” “calculating,” “determining,” “presenting,” “displaying,” or the like may refer to actions or processes of a machine (e.g., a computer) that manipulates or transforms data represented as physical (e.g., electronic, magnetic, or optical) quantities within one or more memories (e.g., volatile memory, non-volatile memory, or a combination thereof), registers, or other machine components that receive, store, transmit, or display information.

As used herein any reference to “some embodiments,” “one embodiment,” “an embodiment,” “in some examples,” or variations thereof means that a particular element, feature, structure, characteristic, operation, or the like described in connection with the embodiment is comprised in at least one embodiment, but not every embodiment necessarily comprises the particular element, feature, structure, characteristic, operation, or the like. Different instances of such a reference in various places in the specification do not necessarily all refer to the same embodiment, although they may in some cases. Moreover, different instances of such a reference may describe elements, features, structures, characteristics, operations, or the like be combined in any manner as an embodiment.

As used herein, the terms “comprises,” “comprising,” “comprises,” “including,” “has,” “having” or any other variation thereof, are intended to cover a non-exclusive inclusion. For example, a process, method, article, or apparatus that comprises a list of elements is not necessarily limited to only those elements but may comprise other elements not expressly listed or inherent to such process, method, article, or apparatus. Further, unless the context of use clearly indicates otherwise, “or” refers to an inclusive or and not to an exclusive or. For example, a condition A or B is satisfied by any one of the following: A is true (or present) and B is false (or not present), A is false (or not present) and B is true (or present), and both A and B are true (or present).

The term “set” is intended to mean a collection of elements and may be a null set (i.e., a set containing zero elements) or may comprise one, two, or more elements. A “subset” is intended to mean a collection of elements that are all elements of a set, but that does not comprise other elements of the set. A first subset of a set may comprise zero, one, or more elements that are also elements of a second subset of the set. The first subset may be said to be a subset of the second subset if all the elements of the first subset are elements of the second subset, while also being a subset of the set. However, if all the elements of the second subset are also elements of the first subset (in addition to all the elements of the first subset being elements of the second subset), the first subset and the second subset are a single subset/not distinct.

For the purposes of the present disclosure, the term “a” or “an” entity refers to one or more of that entity. As such, the terms “a” or “an”, “one or more”, and “at least one” may be used interchangeably herein unless explicitly contradicted by the specification using the word “only one” or similar. For example, “a first element” may functionally be interpreted as “a first one or more elements” or a “first at least one element.” Unless otherwise apparent from the context of use, reference in the present disclosure to a same set of “one or more processors” (or a same “plurality of processors,” etc.) performing multiple operations may encompass implementations in which performance of the operations is divided among the processor(s) in any suitable way. For example, “generating, by one or more processors, X; and generating, by the one or more processors, Y” may encompass: (1) implementations in which a first subset of the processors (e.g., in a first computing device) generates X and an entirely distinct, second subset of the processors (e.g., in a different, second computing device) independently generates Y; (2) implementations in which one or more or all of the processor(s) (e.g., one or multiple processors in the same device, or multiple processors distributed among multiple devices) contribute to the generation of X and/or Y; and (3) other variations. This may similarly be applied to any other component or feature similarly recited (e.g., as “a component”, “a feature”, “one or more components”, “one or more features”, “a plurality of components”, “a plurality of features”). Moreover, the performance of certain of the operations may be distributed among the one or more components, not only residing within a single machine, but deployed across a number of machines. The set of components may be located in a single geographic location (e.g., within a home environment, an office environment, a cloud environment). In other example embodiments, the set of components may be distributed across two or more geographic locations. Further, “a machine-learned model”, equivalent terms (e.g., “machine learning model,” “machine-learning model,” “machine-learned component”, “artificial intelligence”, “artificial intelligence component”), or species thereof (e.g., “a large language model”, “a neural network”) may comprise a single machine-learned model or multiple machine-learned models, such as a pipeline comprising two or more machine-learned models arranged in series and/or parallel, an agentic framework of machine-learned models, or the like.

An “artificial intelligence” or “artificial intelligence component” may comprise a machine-learned model. A machine-learned model may comprise a hardware and/or software architecture having structural hyperparameters defining the model's architecture and/or one or more parameters (e.g., coefficient(s), weight(s), biase(s), activation function(s) and/or action function type(s) in examples where the activation function and/or function type is determined as part of training, clustering centroid(s)/medoid(s), partition(s), number of trees, tree depth, split parameters) determined as a result of training the machine-learned model based at least in part on training hyperparameters (e.g., for supervised, semi-supervised, and reinforcement learning models) and/or by iteratively operating the machine-learned model according to the training hyperparameters (e.g., for unsupervised machine-learned models).

In some examples, structural hyperparameter(s) may define component(s) of the model's architecture and/or their configuration/order, such as, for example, the configuration/order specifying which input(s) are provided to one component and which output(s) of that component are provided as input to other component(s) of the machine-learned model; a number, type, and/or configuration of component(s) per layer; a number of layers of the model; a number and/or type of input nodes in an input layer of the model; a number and/or type of nodes in a layer; a number and/or type of output nodes of an output layer of the model; component dimension (e.g., input size versus output size); a number of trees; a maximum tree depth; node split parameters; minimum number of samples in a leaf node of a tree; and/or the like. The component(s) of the model may comprise one or more activation functions and/or activation function type(s) (e.g., gated linear unit (GLU), such as a rectified linear unit (ReLU), leaky RELU, Gaussian error linear unit (GELU), Swish, hyperbolic tangent), one or more attention mechanism and/or attention mechanism types (e.g., self-attention, cross-attention), nodes and split indications and/or probabilities in a decision tree, and/or various other component(s) (e.g., adding and/or normalization layer, pooling layer, filter). Various combinations of any these components (as defined by the structural hyperparameter(s)) may result in different types of model architectures, such as a transformer-based machine-learned model (e.g., encoder-only model(s), encoder-decoder model(s), decoder-only models, generative pre-trained transformer(s) (GPT(s))), neural network(s), multi-layer perceptron(s), Kolmogorov-Arnold network(s), clustering algorithm(s), support vector machine(s), gradient boosting machine(s), and/or the like. The structural parameters and components a machine-learned model comprises may vary depending on the type of machine-learned model.

Training hyperparameter(s) may be used as part of training or otherwise determining the machine-learned model. In some examples, the training hyperparameter(s), in addition to the training data and/or input data, may affect determining the parameter(s) of the target machine-learned model. Using a different set of training hyperparameters to train two machine-learned models that have the same architecture (i.e., the same structural hyperparameters) and using the same training data may result in the parameters of the first machine-learned model differing from the parameters of the second machine-learned model. Despite having the same architecture and having been trained using the same training data, such machine-learned models may generate different outputs from each other, given the same input data. Accordingly, accuracy, precision, recall, and/or bias may vary between such machine-learned models.

In some examples, training hyperparameter(s) may comprise a train-test split ratio, activation function and/or activation function type (e.g., in examples like Kolmogorov-Arnold networks (KANs) where the activation function type is determined as part of training from an available set of activation functions and/or limits on the activation function parameters specified by the training hyperparameters), training stage(s) (e.g., using a first set of hyperparameters for a first epoch of training, a second set of hyperparameters for a second epoch of training), a batch size and/or number of batches of data in a training epoch, a number of epochs of training, the loss function used (e.g., L1, L2, Huber, Cauchy, cross entropy), the component(s) of the machine-learned model that are altered using the loss for a particular batch or during a particular epoch of training (e.g., some components may be “frozen,” meaning their parameters are not altered based on the loss), learning rate, learning rate optimization algorithm type (e.g., gradient descent, adaptive, stochastic) used to determine an alteration to one or more parameters of one or more components of the machine-learned model to reduce the loss determined by the loss function, learning rate scheduling, and/or the like.

In some examples, the structural hyperparameters and/or the training hyperparameters may be determined by a hyperparameter optimization algorithm or based on user input, such as a software component written by a user or generated by a machine-learned model. The machine-learned model may comprise any type of model configured, trained, and/or the like to generate a prediction output for a model input. In some examples, any of the logic, component(s), routines, and/or the like discussed herein may be implemented as a machine-learned model.

The machine-learned model may comprise one or more of any type of machine-learned model including one or more supervised, unsupervised, semi-supervised, and/or reinforcement learning models. Training a machine-learned model may comprise altering one or more parameters of the machine-learned model (e.g., using a loss optimization algorithm) to reduce a loss. Depending on whether the machine-learned model is supervised, semi-supervised, unsupervised, etc. this loss may be determined based at least in part on a difference between an output generated by the model and ground truth data (e.g., a label, an indication of an outcome that resulted from a system using the output), a cost function, a fit of the parameter(s) to a set of data, a fit of an output to a set of data, and/or the like. In some examples, determining an output by a machine-learned model may comprise executing a set of inference operations executed by the machine-learned model according to the target machine-learned model's parameter(s) and structural hyperparameter(s) and using/operating on a set of input data.

Moreover, any discussion of receiving data associated with an individual that may be protected, confidential, or otherwise sensitive information, is understood to have been preceded by transmitting a notice of use of the data to a computing device, account, or other identifier (collectively, “identifier”) associated with the individual, receiving an indication of authorization to use the data from the identifier, and/or providing a mechanism by which a user may cause use of the data to cease or a copy of the data to be provided to the user.

Upon reading this disclosure, those of skill in the art will appreciate still additional alternative structural and functional designs through the principles disclosed herein. Therefore, while particular embodiments and applications have been illustrated and described, it is to be understood that the disclosed embodiments are not limited to the precise construction and components disclosed herein. Various modifications, changes and variations, which will be apparent to those skilled in the art, may be made in the arrangement, operation and details of the method and apparatus disclosed herein without departing from the spirit and scope defined in the appended claims.

The patent claims at the end of this patent application are not intended to be construed under 35 U.S.C. § 112(f) unless traditional means-plus-function language is expressly recited, such as “means for” or “step for” language being explicitly recited in the claim(s).

### V. EXAMPLES

Some embodiments of the present disclosure may be implemented by one or more computing devices, entities, and/or systems described herein to perform one or more example operations, such as those outlined below. The examples are provided for explanatory purposes. Although the examples outline a particular sequence of steps/operations, each sequence may be altered without departing from the scope of the present disclosure. For example, some of the steps/operations may be performed in parallel or in a different sequence that does not materially impact the function of the various examples. In other examples, different components of an example device or system that implements a particular example may perform functions at substantially the same time or in a specific sequence.

Moreover, although the examples may outline a system or computing entity with respect to one or more steps/operations, each step/operation may be performed by any one or combination of computing devices, entities, and/or systems described herein. For example, a computing system may comprise a single computing entity that is configured to perform all of the steps/operations of a particular example. In addition, or alternatively, a computing system may comprise multiple dedicated computing entities that are respectively configured to perform one or more of the steps/operations of a particular example. By way of example, the multiple dedicated computing entities may coordinate to perform all of the steps/operations of a particular example.

Example 1. A computer-implemented method comprising receiving, by one or more processors, an entity cohort file that identifies a plurality of entity attributes for an entity within an entity cohort, wherein the plurality of attributes comprises a first set of binary coded attributes and a second set of categorical attributes; extracting, by the one or more processors, a cohort-level optimization dataset from the entity cohort file that identifies a subset of target entities from the entity cohort that comprises the entity; generating, by the one or more processors and using a first predictive model, a scaled risk score for the entity based on the first set of binary coded attributes; generating, by the one or more processors and using a second predictive model, a scaled event score for the entity based on the second set of categorical attributes; generating, by the one or more processors, a cohort score for the entity cohort file based on the scaled risk score, the scaled event score, and the subset of target entities; and storing, by the one or more processors, a compressed entity cohort file that identifies the cohort score, the subset of target entities, and an entity-level score for each entity within the subset of target entities.

Example 2. The computer-implemented method of example 1, wherein the compressed entity cohort file is stored in association with a plurality of compressed entity cohort files respectively corresponding to a plurality of entity cohorts, and the computer-implemented method further comprises initiating a presentation of a selection interface to a user that comprises a plurality of selectable icons respectively corresponding to the plurality of entity cohorts.

Example 3. The computer-implemented method of example 2, further comprising receiving location data associated with a user of the selection interface; identifying a portion of the plurality of entity cohorts based on the location data; and modifying the selection interface to adjust a focus to the portion of the plurality of entity cohorts.

Example 4. The computer-implemented method of any of examples 2 through 3, further comprising arranging the plurality of selectable icons within the selection interface based on the cohort score, wherein the plurality of selectable icons is arranged in accordance with a magnitude of each of a plurality of cohort scores respectively corresponding to the plurality of entity cohorts.

Example 5. The computer-implemented method of any of the preceding examples, wherein the first set of binary coded attributes correspond to a plurality of codes defined within a coding domain and generating a scaled risk score for the entity based on the first set of binary coded attributes comprises generating, using a first branch of the first predictive model, a plurality of code predictions for the plurality of codes, respectively; generating, using a second branch of the first predictive model, a simulated engagement score for the entity based the second set of categorical attributes; generating, using an aggregation layer of the first predictive model, a risk score for the entity based on an aggregation of the plurality of code predictions and the simulated engagement score; and applying, using a scaling layer of the first predictive model, a first scaling coefficient to the risk score to generate the scaled risk score.

Example 6. The computer-implemented method of example 5, wherein the first branch of the first predictive model comprises a model ensemble that comprises a rule-based risk prediction model, a machine learned risk prediction model, and routing logic, and generating a code prediction of the plurality of code predictions for a code of the plurality of codes comprises determining, using the routing logic, a processing route for the code; and responsive to the processing route identifying the machine learned prediction model, inputting a third set of historical attributes for the entity to the machine learned prediction model to receive the code prediction.

Example 7. The computer-implemented method of example 6, wherein the first branch of the first predictive model further comprises a normalization layer and generating the code prediction further comprises normalizing the code prediction based on a code prediction distribution comprising a respective code prediction for each entity within the entity cohort.

Example 8. The computer-implemented method of any of the preceding examples, wherein generating the scaled event score for the entity based on the second set of categorical attributes comprises generating, using the second predictive model, an event prediction for the entity based on the second set of categorical attributes; and applying a second scaling coefficient to the event prediction to generate the scaled event score.

Example 9. The computer-implemented method of example 8, wherein second predictive model comprises a graph-based causal model with a plurality of nodes that correspond to the second set of categorical attributes.

Example 10. The computer-implemented method of any of examples 8 through 9, wherein the risk score is a first data type, and the event score is a second data type that is incompatible with the first data type, and the first scaling coefficient and the second scaling coefficient are defined by a compatibility ruleset for transforming the first data type and the second data type to a compatible data type.

Example 11. A system comprising one or more processors; and one or more memories storing processor-executable instructions that, when executed by the one or more processors, cause the one or more processors to perform operations comprising receiving an entity cohort file that identifies a plurality of entity attributes for an entity within an entity cohort, wherein the plurality of attributes comprises a first set of binary coded attributes and a second set of categorical attributes; extracting a cohort-level optimization dataset from the entity cohort file that identifies a subset of target entities from the entity cohort that comprises the entity; generating, using a first predictive model, a scaled risk score for the entity based on the first set of binary coded attributes; generating, using a second predictive model, a scaled event score for the entity based on the second set of categorical attributes; generating a cohort score for the entity cohort file based on the scaled risk score, the scaled event score, and the subset of target entities; and storing a compressed entity cohort file that identifies the cohort score, the subset of target entities, and an entity-level score for each entity within the subset of target entities.

Example 12. The system of example 11, wherein the compressed entity cohort file is stored in association with a plurality of compressed entity cohort files respectively corresponding to a plurality of entity cohorts, and the operations further comprise initiating a presentation of a selection interface to a user that comprises a plurality of selectable icons respectively corresponding to the plurality of entity cohorts.

Example 13. The system of example 12, wherein the operations further comprise receiving location data associated with a user of the selection interface; identifying a portion of the plurality of entity cohorts based on the location data; and modifying the selection interface to adjust a focus to the portion of the plurality of entity cohorts.

Example 14. The system of any of examples 12 through 13, wherein the operations further comprise arranging the plurality of selectable icons within the selection interface based on the cohort score, wherein the plurality of selectable icons is arranged in accordance with a magnitude of each of a plurality of cohort scores respectively corresponding to the plurality of entity cohorts.

Example 15. The system of any of examples 11 through 14, wherein the first set of binary coded attributes correspond to a plurality of codes defined within a coding domain and generating a scaled risk score for the entity based on the first set of binary coded attributes comprises generating, using a first branch of the first predictive model, a plurality of code predictions for the plurality of codes, respectively; generating, using a second branch of the first predictive model, a simulated engagement score for the entity based the second set of categorical attributes; generating, using an aggregation layer of the first predictive model, a risk score for the entity based on an aggregation of the plurality of code predictions and the simulated engagement score; and applying, using a scaling layer of the first predictive model, a first scaling coefficient to the risk score to generate the scaled risk score.

Example 16. The system of example 15, wherein the first branch of the first predictive model comprises a model ensemble that comprises a rule-based risk prediction model, a machine learned risk prediction model, and routing logic, and generating a code prediction of the plurality of code predictions for a code of the plurality of codes comprises determining, using the routing logic, a processing route for the code; and responsive to the processing route identifying the machine learned prediction model, inputting a third set of historical attributes for the entity to the machine learned prediction model to receive the code prediction.

Example 17. One or more non-transitory computer-readable media storing processor-executable instructions that, when executed by one or more processors, cause the one or more processors to perform operations comprising receive an entity cohort file that identifies a plurality of entity attributes for an entity within an entity cohort, wherein the plurality of attributes comprises a first set of binary coded attributes and a second set of categorical attributes; extract a cohort-level optimization dataset from the entity cohort file that identifies a subset of target entities from the entity cohort that comprises the entity; generate, using a first predictive model, a scaled risk score for the entity based on the first set of binary coded attributes; generate, using a second predictive model, a scaled event score for the entity based on the second set of categorical attributes; generate a cohort score for the entity cohort file based on the scaled risk score, the scaled event score, and the subset of target entities; and store a compressed entity cohort file that identifies the cohort score, the subset of target entities, and an entity-level score for each entity within the subset of target entities.

Example 18. The one or more non-transitory computer-readable media of example 17, wherein generating the scaled event score for the entity based on the second set of categorical attributes comprises generating, using the second predictive model, an event prediction for the entity based on the second set of categorical attributes; and applying a second scaling coefficient to the event prediction to generate the scaled event score.

Example 19. The one or more non-transitory computer-readable media of example 18, wherein second predictive model comprises a graph-based causal model with a plurality of nodes that correspond to the second set of categorical attributes.

Example 20. The one or more non-transitory computer-readable media of any of examples 18 through 19, wherein the risk score is a first data type, and the event score is a second data type that is incompatible with the first data type, and the first scaling coefficient and the second scaling coefficient are defined by a compatibility ruleset for transforming the first data type and the second data type to a compatible data type.

Example 21. The computer-implemented method of example 1, wherein the method further comprises training a machine learned risk prediction model and a simulation model of the first predictive model.

Example 22. The computer-implemented method of example 21, wherein the training is performed by the one or more processors.

Example 23. The computer-implemented method of example 21, wherein the one or more processors are comprised in a first computing entity; and the training is performed by one or more other processors comprised in a second computing entity.

Example 24. The system of example 11, wherein the one or more processors are further configured to train a machine learned risk prediction model and a simulation model of the first predictive model.

Example 25. The system of example 24, wherein the one or more processors are comprised in a first computing entity; and the machine learned risk prediction model and the simulation model are trained by one or more other processors comprised in a second computing entity.

Example 26. The one or more non-transitory computer-readable media of example 17, wherein the instructions further cause the one or more processors to train a machine learned risk prediction model and a simulation model of the first predictive model.

Example 27. The one or more non-transitory computer-readable media of example 26, wherein the one or more processors are comprised in a first computing entity; and the machine learned risk prediction model and the simulation model are trained by one or more other processors comprised in a second computing entity.

1. A computer-implemented method comprising:
receiving, by one or more processors, an entity cohort file that identifies a plurality of entity attributes for an entity within an entity cohort, wherein the plurality of entity attributes comprises a first set of binary coded attributes corresponding to a plurality of codes defined within a coding domain and a second set of categorical attributes;
extracting, by the one or more processors, a cohort-level optimization dataset from the entity cohort file that identifies a subset of target entities from the entity cohort that comprises the entity;
generating, by the one or more processors and using a first predictive model, a scaled risk score for the entity based on the first set of binary coded attributes, wherein generating the scaled risk score using the first predictive model comprises:
generating a plurality of code predictions for the plurality of codes, respectively, and a simulated engagement score for the entity based on the second set of categorical attributes,
generating a risk score for the entity based on an aggregation of the plurality of code predictions and the simulated engagement score, and
applying a first scaling coefficient to the risk score to generate the scaled risk score;
generating, by the one or more processors and using a second predictive model, a scaled event score for the entity based on the second set of categorical attributes;
generating, by the one or more processors, a cohort score for the entity cohort file based on the scaled risk score, the scaled event score, and the subset of target entities; and
storing, by the one or more processors, a compressed entity cohort file that identifies the cohort score, the subset of target entities, and an entity-level score for each entity within the subset of target entities.

2. The computer-implemented method of claim 1, wherein the compressed entity cohort file is stored in association with a plurality of compressed entity cohort files respectively corresponding to a plurality of entity cohorts, and the computer-implemented method further comprises:
initiating a presentation of a selection interface to a user device that comprises a plurality of selectable icons respectively corresponding to the plurality of entity cohorts.

3. The computer-implemented method of claim 2, further comprising:
receiving location data associated with the user device of the selection interface;
identifying a portion of the plurality of entity cohorts based on the location data; and
modifying the selection interface to adjust a focus to the portion of the plurality of entity cohorts.

4. The computer-implemented method of claim 2, further comprising:
arranging the plurality of selectable icons within the selection interface based on the cohort score, wherein the plurality of selectable icons is arranged in accordance with a magnitude of each of a plurality of cohort scores respectively corresponding to the plurality of entity cohorts.

5. The computer-implemented method of claim 1, wherein the plurality of code predictions is generated using a first branch of the first predictive model, the simulated engagement score is generated using a second branch of the first predictive model, the risk score is generated using an aggregation layer of the first predictive model, and the first scaling coefficient is applied to the risk score to generate the scaled risk score using a scaling layer of the first predictive model.

6. The computer-implemented method of claim 5, wherein the first branch of the first predictive model comprises a model ensemble that comprises a rule-based risk prediction model, a machine learned risk prediction model, and routing logic, and generating a code prediction of the plurality of code predictions for a code of the plurality of codes comprises:
determining, using the routing logic, a processing route for the code; and
responsive to the processing route identifying the machine learned risk prediction model, inputting a third set of historical attributes for the entity to the machine learned risk prediction model to receive the code prediction.

7. The computer-implemented method of claim 6, wherein the first branch of the first predictive model further comprises a normalization layer and generating the code prediction further comprises normalizing the code prediction based on a code prediction distribution comprising a respective code prediction for each entity within the entity cohort.

8. The computer-implemented method of claim 1, wherein generating the scaled event score for the entity based on the second set of categorical attributes comprises:
generating, using the second predictive model, an event score for the entity based on the second set of categorical attributes; and
applying a second scaling coefficient to the event score to generate the scaled event score.

9. The computer-implemented method of claim 8, wherein the second predictive model comprises a graph-based causal model with a plurality of nodes that correspond to the second set of categorical attributes.

10. The computer-implemented method of claim 8, wherein the risk score is a first data type, and the event score is a second data type that is incompatible with the first data type, and the first scaling coefficient and the second scaling coefficient are defined by a compatibility ruleset for transforming the first data type and the second data type to a compatible data type.

11. A system comprising:
one or more processors; and
one or more memories storing processor-executable instructions that, when executed by the one or more processors, cause the one or more processors to perform operations comprising:
receiving an entity cohort file that identifies a plurality of entity attributes for an entity within an entity cohort, wherein the plurality of entity attributes comprises a first set of binary coded attributes corresponding to a plurality of codes defined within a coding domain and a second set of categorical attributes;
extracting a cohort-level optimization dataset from the entity cohort file that identifies a subset of target entities from the entity cohort that comprises the entity;
generating, using a first predictive model, a scaled risk score for the entity based on the first set of binary coded attributes, wherein generating the scaled risk score comprises:
generating, using the first predictive model, a plurality of code predictions for the plurality of codes, respectively, and a simulated engagement score for the entity based on the second set of categorical attributes,
generating, using the first predictive model, a risk score for the entity based on an aggregation of the plurality of code predictions and the simulated engagement score, and
applying, using the first predictive model, a first scaling coefficient to the risk score to generate the scaled risk score;
generating, using a second predictive model, a scaled event score for the entity based on the second set of categorical attributes;
generating a cohort score for the entity cohort file based on the scaled risk score, the scaled event score, and the subset of target entities; and
storing a compressed entity cohort file that identifies the cohort score, the subset of target entities, and an entity-level score for each entity within the subset of target entities.

12. The system of claim 11, wherein the compressed entity cohort file is stored in association with a plurality of compressed entity cohort files respectively corresponding to a plurality of entity cohorts, and the operations further comprise:
initiating a presentation of a selection interface to a user device that comprises a plurality of selectable icons respectively corresponding to the plurality of entity cohorts.

13. The system of claim 12, wherein the operations further comprise:
receiving location data associated with the user device of the selection interface;
identifying a portion of the plurality of entity cohorts based on the location data; and
modifying the selection interface to adjust a focus to the portion of the plurality of entity cohorts.

14. The system of claim 12, wherein the operations further comprise:
arranging the plurality of selectable icons within the selection interface based on the cohort score, wherein the plurality of selectable icons is arranged in accordance with a magnitude of each of a plurality of cohort scores respectively corresponding to the plurality of entity cohorts.

15. The system of claim 11, wherein the plurality of code predictions is generated using a first branch of the first predictive model, the simulated engagement score is generated using a second branch of the first predictive model, the risk score is generated using an aggregation layer of the first predictive model, and the first scaling coefficient is applied to the risk score to generate the scaled risk score using a scaling layer of the first predictive model.

16. The system of claim 15, wherein the first branch of the first predictive model comprises a model ensemble that comprises a rule-based risk prediction model, a machine learned risk prediction model, and routing logic, and generating a code prediction of the plurality of code predictions for a code of the plurality of codes comprises:
determining, using the routing logic, a processing route for the code; and
responsive to the processing route identifying the machine learned risk prediction model, inputting a third set of historical attributes for the entity to the machine learned risk prediction model to receive the code prediction.

17. One or more non-transitory computer-readable media storing processor-executable instructions that, when executed by one or more processors, cause the one or more processors to perform operations comprising:
receive an entity cohort file that identifies a plurality of entity attributes for an entity within an entity cohort, wherein the plurality of entity attributes comprises a first set of binary coded attributes corresponding to a plurality of codes defined within a coding domain and a second set of categorical attributes;
extract a cohort-level optimization dataset from the entity cohort file that identifies a subset of target entities from the entity cohort that comprises the entity;
generate, using a first predictive model, a scaled risk score for the entity based on the first set of binary coded attributes, wherein generating the scaled risk score comprises:
generating, using the first predictive model, a plurality of code predictions for the plurality of codes, respectively, and a simulated engagement score for the entity based on the second set of categorical attributes,
generating, using the first predictive model, a risk score for the entity based on an aggregation of the plurality of code predictions and the simulated engagement score, and
applying, using the first predictive model, a first scaling coefficient to the risk score to generate the scaled risk score;
generate, using a second predictive model, a scaled event score for the entity based on the second set of categorical attributes;
generate a cohort score for the entity cohort file based on the scaled risk score, the scaled event score, and the subset of target entities; and
store a compressed entity cohort file that identifies the cohort score, the subset of target entities, and an entity-level score for each entity within the subset of target entities.

18. The one or more non-transitory computer-readable media of claim 17, wherein generating the scaled event score for the entity based on the second set of categorical attributes comprises:
generating, using the second predictive model, an event score for the entity based on the second set of categorical attributes; and
applying a second scaling coefficient to the event score to generate the scaled event score.

19. The one or more non-transitory computer-readable media of claim 18, wherein the second predictive model comprises a graph-based causal model with a plurality of nodes that correspond to the second set of categorical attributes.

20. The one or more non-transitory computer-readable media of claim 18, wherein the risk score is a first data type, and the event score is a second data type that is incompatible with the first data type, and the first scaling coefficient and the second scaling coefficient are defined by a compatibility ruleset for transforming the first data type and the second data type to a compatible data type.
